(19) United States
(12) Patent Application Publication
(10) Pub. No.: US 2026/0268943 A1
(43) Pub. Date: Sep. 10, 2026

(54) THREE-DIMENSIONAL MEMORY DEVICE WITH SPLIT DIELECTRIC WALL STRUCTURES AND METHODS FOR FORMING THE SAME

(71) Applicant: Sandisk Technologies, Inc., Milpitas, CA (US)

(72) Inventor: Akihiro TOBIOKA, Yokkaichi (JP)

(21) Appl. No.: 19/073,808

(22) Filed: Mar. 7, 2025

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

A semiconductor structure includes a pair of multi-tier layer stacks laterally extending along a first horizontal direction and laterally spaced apart from each other along a second horizontal direction by a first lateral isolation structure, memory openings vertically extending through a respective one of the multi-tier layer stacks, and memory opening fill structures located in a respective one of the memory openings. The first lateral isolation structure includes: a first primary dielectric wall structure laterally extending through the first memory array region and extending into a first peripheral portion of the inter-array region, a complementary dielectric wall structure laterally extending through the inter-array region and laterally spaced from the first primary dielectric wall structure by a first lateral gap along the first horizontal direction, and a first dielectric pillar structure that fills the first lateral gap and contacts the first primary dielectric wall structure and the complementary dielectric wall structure.

### FIELD

The present disclosure generally relates to the field of semiconductor devices, and particularly to a three-dimensional memory device containing split dielectric wall structures and methods for forming the same.

### BACKGROUND

A three-dimensional memory device includes vertical NAND strings which extend through an alternating stacks of word lines and insulating layers.

### SUMMARY

According to an aspect of the present disclosure, a semiconductor structure is provided, which comprises: a pair of multi-tier layer stacks laterally extending along a first horizontal direction and laterally spaced apart from each other along a second horizontal direction by a first lateral isolation structure, wherein each of the multi-tier layer stacks comprises a first-tier alternating stack of first insulating layers and first electrically conductive layers, and further comprises a second-tier alternating stack of second insulating layers and second electrically conductive layers that overlies the first-tier alternating stack, wherein the semiconductor structure comprises a first memory array region and a second memory array region that are laterally spaced apart from each other along the first horizontal direction by an inter-array region; memory openings vertically extending through a respective one of the multi-tier layer stacks and located in a respective one of the first memory array region and the second memory array region; and memory opening fill structures located in a respective one of the memory openings and comprising a vertical semiconductor channel and respective vertical stack of memory elements. The first lateral isolation structure comprises: a first primary dielectric wall structure laterally extending through the first memory array region and extending into a first peripheral portion of the inter-array region; a complementary dielectric wall structure laterally extending through the inter-array region and laterally spaced from the first primary dielectric wall structure by a first lateral gap along the first horizontal direction; and a first dielectric pillar structure that fills the first lateral gap and contacts the first primary dielectric wall structure and the complementary dielectric wall structure.

According to another aspect of the present disclosure, a method of forming a semiconductor structure is provided, which comprises: forming a first-tier structure comprising first-tier alternating stacks of first insulating layers and first sacrificial material layers, wherein the first-tier alternating stacks laterally extend along a first horizontal direction and are laterally spaced apart from each other by sacrificial first-tier wall structures; forming a second-tier structure comprising second-tier alternating stacks of second insulating layers and second sacrificial material layers over the first-tier structure, wherein the second-tier alternating stacks laterally extend along the first horizontal direction and are laterally spaced apart from each other by second-tier lateral spacer structures, wherein a neighboring pair of second-tier alternating stacks is laterally spaced apart from each other by a first second-tier lateral spacer structure of the second-tier lateral spacer structures, and wherein the first second-tier lateral spacer structure comprises a combination of at least one primary sacrificial second-tier wall structure, a complementary sacrificial second-tier wall structure that is laterally spaced from the at least one primary sacrificial second-tier wall structure by at least one second-tier lateral gap, and at least one dielectric pillar structure filling the at least one second-tier lateral gap; forming memory openings in a first memory array region and in a second memory array region at least through a respective vertical stack of a respective one of the first-tier alternating stacks and through a respective one of the second-tier alternating stacks; forming memory opening fill structures in the memory openings, wherein each of the memory opening fill structures comprises a vertical semiconductor channel and a respective vertical stack of memory elements; replacing the complementary sacrificial second-tier wall structure and a first portion of one of the sacrificial first-tier wall structures with a complementary dielectric wall structure; forming lateral isolation trenches by removing at least the at least one primary sacrificial second-tier wall structure and remaining portions of said one of the sacrificial first-tier wall structures; and replacing remaining portions of the first sacrificial material layers and remaining portions of the second sacrificial material layers with first electrically conductive layers and second electrically conductive layers, respectively.

### BRIEF DESCRIPTION OF DRAWINGS

Within the set of figures including FIG. 1A-1E, 4A-10E, 12A-13E, 15A-15E, and 17A-17E, each figure is labeled with a combination of a figure numeral and an alphabetical suffix. Each set of figures with the same figure numeral corresponds to views for an exemplary structure at a same processing step. Each figure with the alphabetical suffix “B” is a top-down view of the exemplary structure. Each figure with the alphabetical suffix “A” is a first vertical cross-sectional view along a vertical plane A-A′ in the figure with the same figure numeral and the alphabetical suffix “B.” Each figure with the alphabetical suffix “C” is a second vertical cross-sectional view along a vertical plane C-C′ in the figure with the same figure numeral and the alphabetical suffix “B.” Each figure with the alphabetical suffix “D” is a third vertical cross-sectional view along a vertical plane D-D′ in the figure with the same figure numeral and the alphabetical suffix “B.” Each figure with the alphabetical suffix “E” is a fourth vertical cross-sectional view along a vertical plane E-E′ in the figure with the same figure numeral and the alphabetical suffix “B.”

FIG. 1A-1E are various views of an exemplary structure after formation of a first-tier vertically alternating sequence of first insulating layers and first sacrificial material layers and formation of first-tier stepped cavities according to an embodiment of the present disclosure.

FIG. 2A-2C are sequential vertical cross-sectional views of a region of the exemplary structure during thickening of physically-exposed portions of the first sacrificial material layers according to an embodiment of the present disclosure.

FIG. 3A-3E are sequential vertical cross-sectional views of a region of the exemplary structure during a sequence of processing steps that may be employed to locally thicken the physically-exposed portions of the first sacrificial material layers according to an embodiment of the present disclosure.

FIG. 4A-4E are various view of the exemplary structure after local thickening of the physically exposed portions of the first sacrificial material layers and formation of first-tier retro-stepped dielectric material portions according to an embodiment of the present disclosure.

FIG. 5A-5E are various views of the exemplary structure after formation of various first-tier openings and various sacrificial first-tier opening fill structures according to an embodiment of the present disclosure.

FIG. 6A-6E are various views of the exemplary structure after formation of a second-tier vertically alternating sequence of second insulating layers and second sacrificial material layers, second-tier retro-stepped dielectric material portions, and dielectric pillar structures according to an embodiment of the present disclosure.

FIG. 7A-7E are various views of the exemplary structure after formation of various second-tier openings and various sacrificial second-tier opening fill structures according to an embodiment of the present disclosure.

FIG. 8A-8E are various views of the exemplary structure after formation of inter-tier support openings and line trenches according to an embodiment of the present disclosure.

FIG. 9A-9E are various view of the exemplary structure after formation of support pillar structures and complementary dielectric wall structures according to an embodiment of the present disclosure.

FIG. 10A-10E are various views of the exemplary structure after formation of cavities in inter-tier memory openings according to an embodiment of the present disclosure.

FIG. 11A-11D illustrate sequential vertical cross-sectional views of a memory opening during formation of a memory opening fill structure according to an embodiment of the present disclosure.

FIG. 12A-12E are various views of the exemplary structure after formation of memory opening fill structures in each memory opening according to an embodiment of the present disclosure.

FIG. 13A-13E are various views of the exemplary structure after formation of contact openings according to an embodiment of the present disclosure.

FIGS. 14A and 14B are sequential vertical cross-sectional views of the exemplary structure during formation of finned contact via cavities and annular insulating spacers according to an embodiment of the present disclosure.

FIG. 15A-15E are various views of the exemplary structure after formation of sacrificial contact via structures according to an embodiment of the present disclosure.

FIG. 16A-16D are sequential vertical cross-sectional views of the exemplary structure during formation of lateral isolation trenches and replacement of the sacrificial material layers with electrically conductive layers according to an embodiment of the present disclosure.

FIG. 17A-17E are various views of the exemplary structure after formation of dielectric wall structures according to an embodiment of the present disclosure.

FIG. 18A-18E are various views of the exemplary structure after formation of various contact via structures according to an embodiment of the present disclosure.

FIG. 19A-19E are various views of a first alternative exemplary structure after formation of various contact via structures according to a first alternative embodiment of the present disclosure.

FIGS. 20, 21 and 22 are top views of the respective second, third and fourth alternative exemplary structures after formation of various contact via structures according to the respective second, third and fourth alternative embodiments of the present disclosure.

### DETAILED DESCRIPTION

As discussed above, the embodiments of the present disclosure are directed to a three-dimensional memory device with multi-tier structures incorporating lateral isolation structures containing dielectric filled gaps between dielectric wall structures and methods for forming the same, the various aspects of which are described below. Multi-tier memory structures may include multi-tier alternating stacks of insulating layers and electrically conductive layers that laterally extend horizontally over relatively long distances. As the number of tiers in the multi-tier memory structures increases, maintaining a uniform and stable width for lateral isolation structures between neighboring multi-tier alternating stacks becomes increasingly difficult as the stack height increases. Embodiments of the present disclosure are directed to structures and methods for increasing the structural stability of the lateral isolation trenches that are used to replace sacrificial material layers with electrically conductive layers by using multiple lateral isolation trenches laterally spaced by a dielectric structural support element, such as a dielectric pillar structure or retro-stepped dielectric material portion including a respective full-height dielectric material sub-portion.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function.

Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow. As used herein, a first surface and a second surface are “vertically coincident” with each other if the second surface overlies or underlies the first surface and there exists a vertical plane or a substantially vertical plane that includes the first surface and the second surface. As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3, and/or 10, and/or 100, and/or 1,000.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

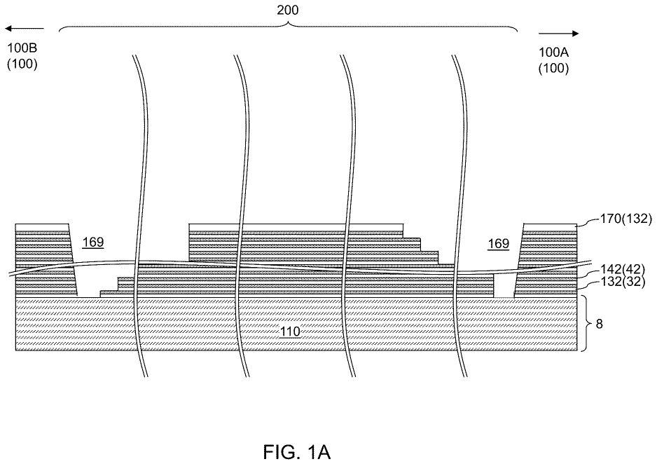

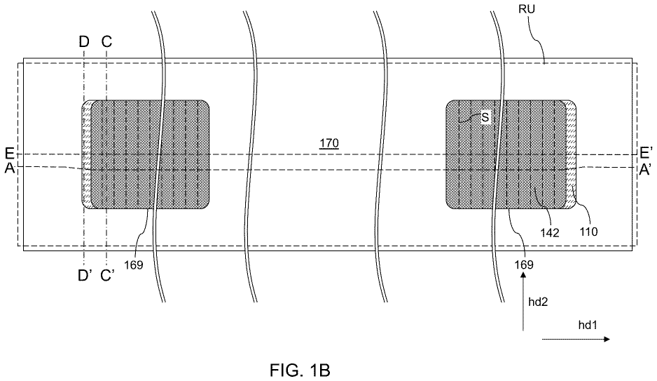

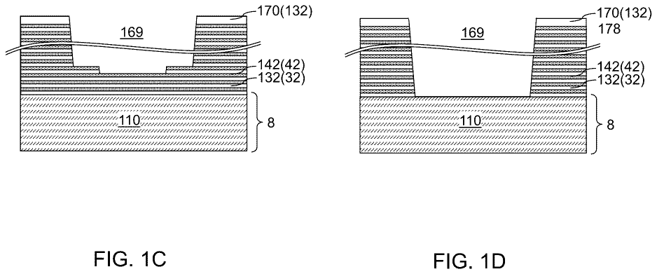

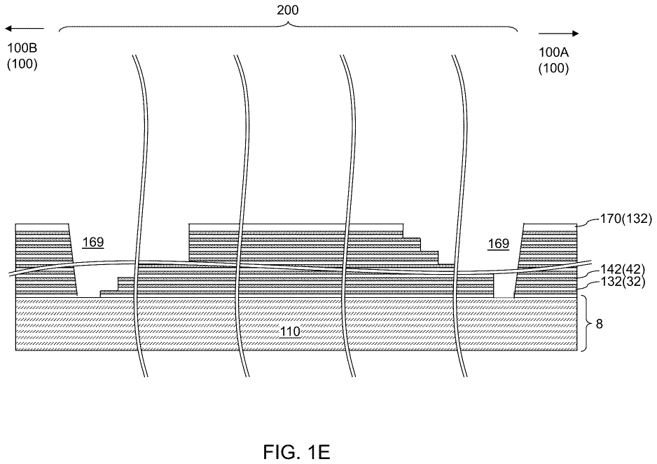

Referring to FIG. 1A-1E, an exemplary structure is illustrated according to an embodiment of the present disclosure. The exemplary structure includes a substrate 8 which may contain an optional semiconductor material layer 110. Optionally, the substrate may additionally comprise an underlying semiconductor material layer (not illustrated), optional semiconductor devices located on the underlying semiconductor material layer (not illustrated), optional lower level dielectric layers (not illustrated), and optional lower metal interconnect structures (not illustrated) underneath the semiconductor material layer 110. The semiconductor material layer 110 may comprise a polycrystalline semiconductor material layer or a single crystalline semiconductor material layer. For example, the substrate 8 may comprise a single crystalline silicon wafer, and the semiconductor material layer 110 may comprise a doped well in an upper portion of the substrate 8 or an epitaxial silicon layer deposited on the top surface of the substrate 8. Alternatively, the substrate 8 may comprise a silicon on insulator (SOI) substrate, in which the semiconductor material layer 110 comprises a silicon layer located over an insulating portion of the substrate 8. Alternatively, a peripheral (i.e., driver) circuit may be located on the substrate 8, and the semiconductor material layer 110 may comprise a polysilicon layer which overlies the peripheral circuit.

A first-tier vertically alternating sequence of first insulating layers 132 and first sacrificial material layers 142 can be formed over the semiconductor material layer 110. Each of the first insulating layers 132 may be formed as a single continuous material layer, and thus, may be referred to as a first continuous insulating layer. Each of the first sacrificial material layers 142 may be formed as a single continuous material layer, and thus, may be formed as a first continuous sacrificial material layer. Each of the first insulating layers 132 and the first sacrificial material layers 142 may have a thickness in a range from 20 nm to 80 nm, although lesser and greater thicknesses may also be employed.

In one embodiment, the first-tier vertically alternating sequence of first insulating layers 132 and first sacrificial material layers 142 may include a periodic repetition of a unit layer stack including a first insulating layer 132 and a first sacrificial material layer 142. The total number of repetitions of the unit layer stack may be in a range from 4 to 1,024, such as from 16 to 256, although lesser and greater numbers of repetitions may also be employed.

The first insulating layers 132 may comprise, and/or may consist essentially of, an insulating material such as undoped silicate glass or a doped silicate glass. The first sacrificial material layers 142 may comprise, and/or may consist essentially of, a sacrificial material such as silicon nitride, a silicon-germanium alloy, organosilicate glass, or a polymer material. Generally, the first sacrificial material layers 142 comprise a material that may be removed selectively to the materials of the first insulating layers 132 and the semiconductor material layer 110. The topmost first insulating layer 132 is herein referred to as a first insulating cap layer 170. The first insulating layers 132 are a first subset of insulating layers 32 that are formed in this processing step and in subsequent processing steps. The first sacrificial material layers 142 are a first subset of sacrificial material layers 42 that are formed in this processing step and in subsequent processing steps.

The exemplary structure may comprise a first memory array region 100A in which first memory arrays are to be subsequently formed, a second memory array region 100B in which second memory arrays are to be subsequently formed, and an inter-array region 200 in which stepped surfaces and layer contact via structures contacting a respective electrically conductive layer are to be subsequently formed. In one embodiment, the first memory array region 100A and the second memory array region 100B can be laterally spaced apart from each other along a first horizontal direction hd1 (which may be a word line direction) by the inter-array region 200.

First stepped surfaces can be formed by patterning the first-tier vertically alternating sequence (132, 142). Generally, the first stepped surfaces may be formed employing any method for forming stepped surfaces as known in the art. For example, a first patterned hard mask layer (not shown) may be formed over the first-tier vertically alternating sequence (132, 142) to define areas in which first stepped surfaces are to be subsequently formed. A first trimmable etch mask layer (not shown) can be formed over the first patterned hard mask layer, and can be lithographically patterned to form slit-shaped openings over peripheral regions of the openings in the first patterned hard mask layer. A unit processing sequence can be repeatedly performed to form first stepped surfaces in the first-tier vertically alternating sequence (132, 142) within the areas of openings in the first patterned hard mask layer. For example, the unit processing sequence may comprise an anisotropic etch process that etches a pair of a first insulating layer 132 and a first sacrificial material layer 142 and a trimming process that isotropically trims the first trimmable etch mask layer. The number of repetitions of the unit processing sequence may be the same as the total number of first sacrificial material layers 142 in the first-tier vertically alternating sequence (132, 142). A first-tier stepped cavity 169 overlying a respective set of first stepped surfaces of the first-tier vertically alternating sequence (132, 142) can be formed within each patterned area of the first-tier vertically alternating sequence (132, 142).

In one embodiment, the vertical steps within each first-tier stepped cavity may be laterally spaced from each other along the first horizontal direction hd1 (which may be a word line direction). In one embodiment, the first-tier stepped cavities may be arranged along a second horizontal direction hd2 (which may be a bit line direction). In one embodiment, the exemplary structure may have a periodic pattern that repeats along the first horizontal direction hd1. Specifically, a repetition unit RU is repeated along the second horizontal direction hd2. In one embodiment, each repetition unit RU may comprise a first-tier stepped cavity. Physically exposed portions of the first continuous sacrificial material layers 142 can be locally thickened underneath the first-tier stepped cavities by depositing and patterning additional sacrificial material thereon.

In one embodiment, the lateral extent of the layers of the first alternating sequence (132, 142) along a first horizontal direction hd1 may vary (e.g., decrease) with a vertical distance from the substrate 8 within each region including a respective set of first stepped surfaces. In one embodiment, each opening in the topmost layer of the first-tier vertically alternating sequence (132, 142) may have a rectangular shape having a pair of lengthwise sides laterally extending along the first horizontal direction hd1 and a pair of widthwise sides laterally extending along a second horizontal direction hd2 that is perpendicular to the first horizontal direction hd1. Each set of first stepped surfaces may comprise vertical steps S, as shown in FIG. 1B. Tapered surfaces may be formed around each first-tier stepped cavity between the stepped surfaces and the topmost horizontal surface of the first-tier vertically alternating sequence (132, 142). Alternative schemes employing repetition of an etch step and a trimming step may be employed to pattern portions of the first-tier vertically alternating sequence (132, 142) that are not masked by the first patterned hard mask layer. The first trimmable etch mask layer and the first patterned hard mask layer can be subsequently removed.

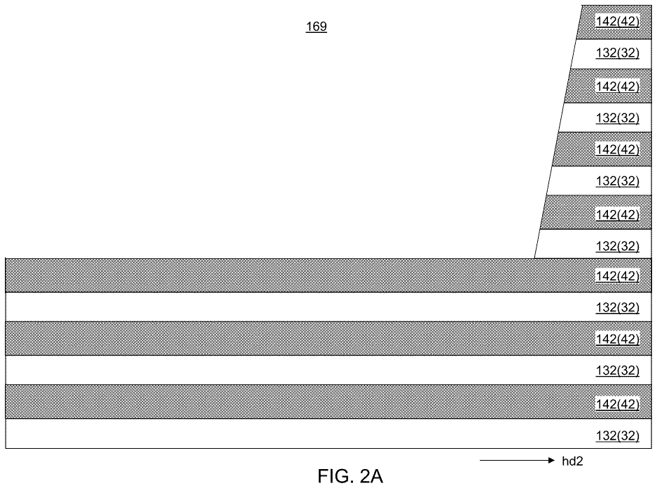

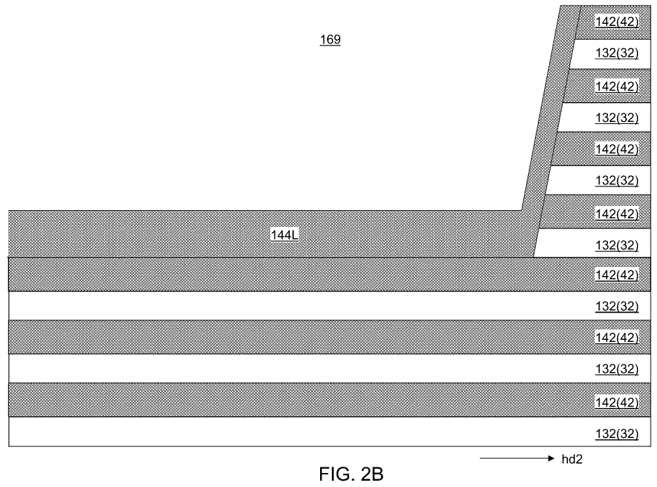

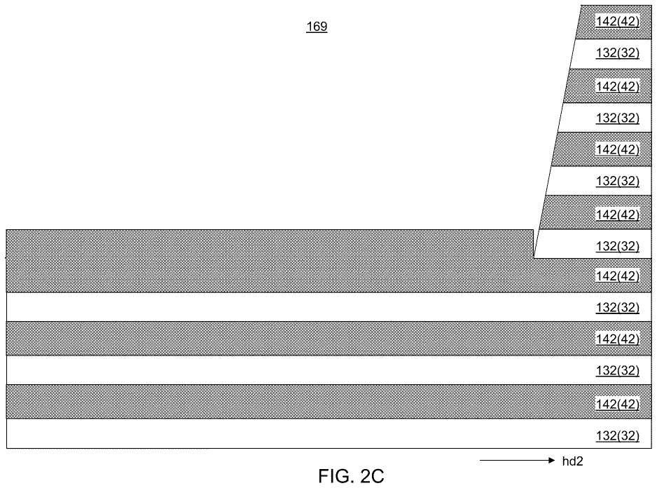

In one embodiment, the physically exposed portions of the first sacrificial material layers 142 can be locally thickened. FIG. 2A-2C are sequential vertical cross-sectional views of a region of the exemplary structure during thickening of physically-exposed portions of the first sacrificial material layers according to an embodiment of the present disclosure.

Referring to FIG. 2A, an anisotropic material deposition process can be performed to anisotropically deposit a same material as the material of the first sacrificial material layers 142 to form a non-conformal sacrificial material layer 144L. In one embodiment, the first sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50% to 300% of the thickness of each first sacrificial material layer 142.

Referring to FIG. 2B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first sacrificial material layers 142 can be incorporated into the respective one of the first sacrificial material layers 142.

Thus, physically-exposed portions of the sacrificial material layers 42 (such as the first sacrificial material layers 142) in the staircase region can be thickened such that the thickened portions of the sacrificial material layers 142 have a thickness in a range from 125% to 250%, such as from 150% to 200%, of the unthickened portion of the first sacrificial material layers 142 (which is the same as the original thickness of each first sacrificial material layers 142). While an embodiment is described in which physically exposed portions of the first sacrificial material layers 142 are locally thickened by anisotropic deposition and isotropic etch-back of a sacrificial material, the physically exposed portions of the first sacrificial material layers 142 may be locally thickened by alternative methods that can selectively increase the thickness of physically exposed portions of the first sacrificial material layers 142.

Referring to FIG. 2C, portions of the non-conformal sacrificial material layer 144L that are deposited outside the areas of the first-tier stepped cavities 169 can be removed, for example, by covering the areas of the first-tier stepped cavities 169 with patterned photoresist materials without covering sidewalls of the first-tier stepped cavities 169, and by performing an etch process that etches unmasked portions of the material of the non-conformal sacrificial material layer 144L. Physically exposed portions of the first sacrificial material layers 142 may be locally thickened within the first-tier stepped cavities 169.

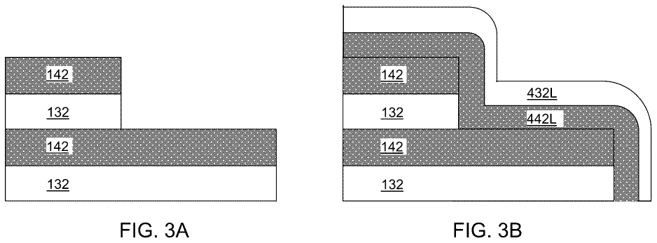

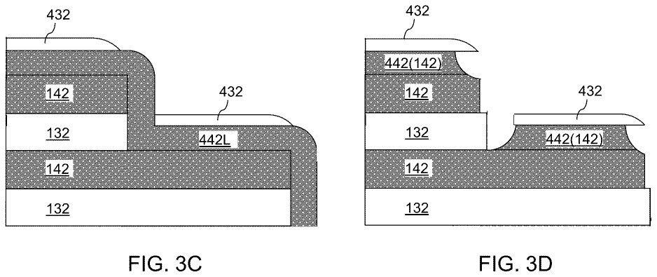

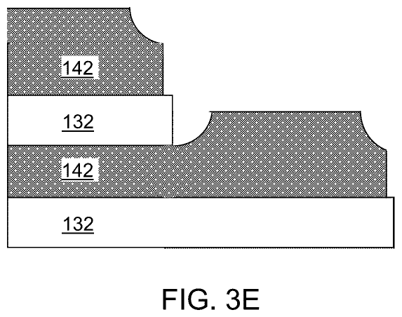

Local thickening of the physically exposed portions of the first sacrificial material layers 142 may also be performed employing alternative methods. FIG. 3A-3E are sequential vertical cross-sectional views of a region of the exemplary structure during a sequence of processing steps that may be employed to locally thicken the physically-exposed portions of the first sacrificial material layers according to an embodiment of the present disclosure.

Referring to FIG. 3A, a region of the first-tier stepped surfaces in a first-tier stepped cavity 169 after the processing steps of FIGS. 1A and 1B is illustrated.

Referring to FIG. 3B, an additive sacrificial material layer 442L can be conformally deposited by a conformal deposition process such as a low pressure chemical vapor deposition process. The thickness of the additive sacrificial material layer 442L may be in a range from 40% to 300%, such as from 60% to 150%, of the thickness of each first sacrificial material layer 142. The additive sacrificial material layer 442L may comprise the same material as the first sacrificial material layers 142. For example, if the first sacrificial material layers 142 comprise silicon nitride, the additive sacrificial material layer 442L may comprise silicon nitride.

Subsequently, a non-conformal cover material layer 432L may be anisotropically deposited. The anisotropic deposition of the non-conformal cover material layer 432L may be effected, for example, by plasma enhanced chemical vapor deposition. The non-conformal cover material layer 432L comprises a material that can function as an etch mask material for subsequently etching unmasked portions of the additive sacrificial material layer 442L. For example, the non-conformal cover material layer 432L may comprise silicon oxide. The vertical thickness of the horizontally-extending portions of the non-conformal cover material layer 432L is greater than the lateral thickness of the vertically-extending portions of the non-conformal cover material layer 432L. The difference between the vertical thickness of the horizontally-extending portions of the non-conformal cover material layer 432L and the lateral thickness of the vertically-extending portions of the non-conformal cover material layer 432L may be in a range from 1.3 to 3.0, such as from 1.5 to 2.0.

Referring to FIG. 3C, an isotropic etch process can be performed to isotropically etch the material of the non-conformal cover material layer 432L. The duration of the isotropic etch process is selected such that the etch distance of the isotropic etch process for the material of the non-conformal cover material layer 432L is greater than the lateral thickness of vertically-extending portions of the non-conformal cover material layer 432L, and is less than the vertical thickness of the horizontally-extending portions of the non-conformal cover material layer 432L. Thus, remaining portions of the non-conformal cover material layer 432L after the isotropic etch process comprise cover material plates 432 that overlie horizontally-extending portions of the additive sacrificial material layer 442L. The cover material plates 432 have a vertical thickness that is not greater than the difference between the vertical thickness of the horizontally-extending portions of the non-conformal cover material layer 432L and the lateral thickness of vertically-extending portions of the non-conformal cover material layer 432L, and may be in a range from 10 nm to 50 nm, although lesser and greater thicknesses may also be employed.

Referring to FIG. 3D, a selective isotropic etch process can be performed to isotropically etch unmasked portions of the additive sacrificial material layer 442L without etching the materials of cover material plates 432 or the first-tier insulating layers 132. The duration of the selective isotropic etch process may be selected such that the etch distance of the selective isotropic etch process for the material of the additive sacrificial material layer 442L is not less than the uniform thickness of the additive sacrificial material layer 442L. Thus, vertically-extending portions of the additive sacrificial material layer 442L are removed by the selective isotropic etch process, while remaining horizontally-extending portions of the additive sacrificial material layer 442L underlie a respective one of the cover material plates 432. The remaining horizontally-extending portions of the additive sacrificial material layer 442L comprise sacrificial material plates 442, which are incorporated into a respective one of the first sacrificial material layers 142.

Referring to FIG. 3E, a selective etch process may be optionally performed to remove the cover material plates 432 without removing the materials of the sacrificial material plates 442 or the first sacrificial material layers 142. The material of sacrificial material plates 442 may be the same as the material of the first sacrificial material layers 142. Thus, the first sacrificial material layers 142 incorporate the sacrificial material plates 442, and are locally thickened in the regions of the first stepped surfaces.

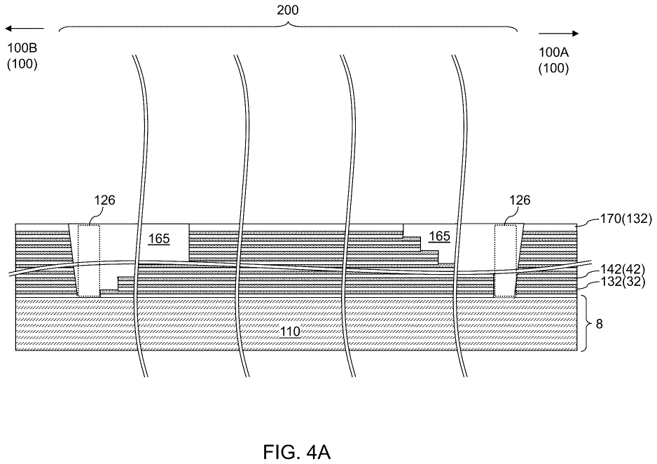

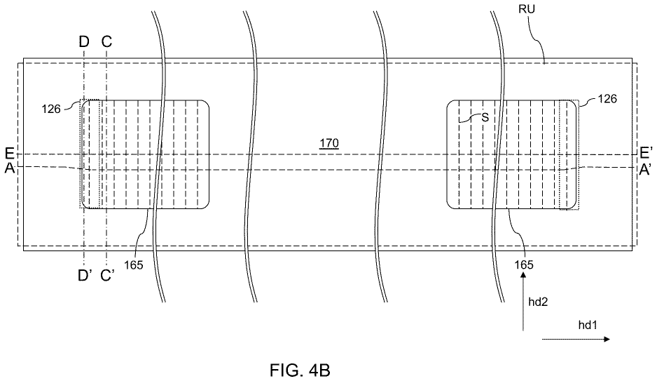

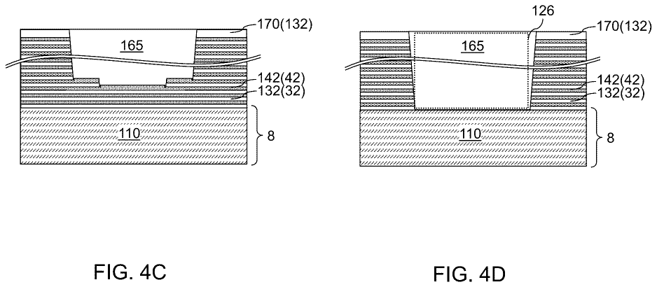

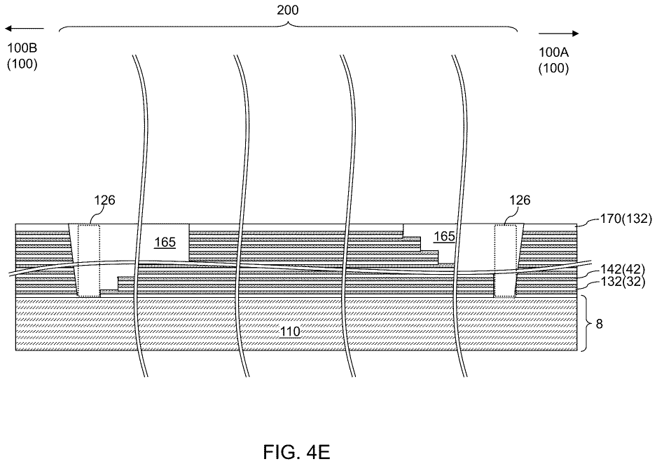

Referring to FIG. 4A-4E, a dielectric fill material can be deposited within each of the first-tier stepped cavities 169 to form first-tier retro-stepped dielectric material portions 165. A first-tier structure is formed, which comprises the first-tier vertically alternating sequence (132, 142) and the first-tier retro-stepped dielectric material portions 165. In one embodiment, a pair of first-tier retro-stepped dielectric material portions 165 that are laterally spaced apart from each other along the first horizontal direction hd1 may be formed within each repetition unit RU. End portions of the first-tier retro-stepped dielectric material portions 165 vertically extend through every layer of the first-tier vertically alternating sequence (132, 142) to the top surface of the semiconductor material layer 110. The end portions comprise first-tier dielectric separators 126.

In an alternative embodiment, the local thickening of the first sacrificial material layers 142 may be omitted if subsequently formed contact via structures do not extend through the respective word lines and select gate electrodes which will replace the sacrificial material layers.

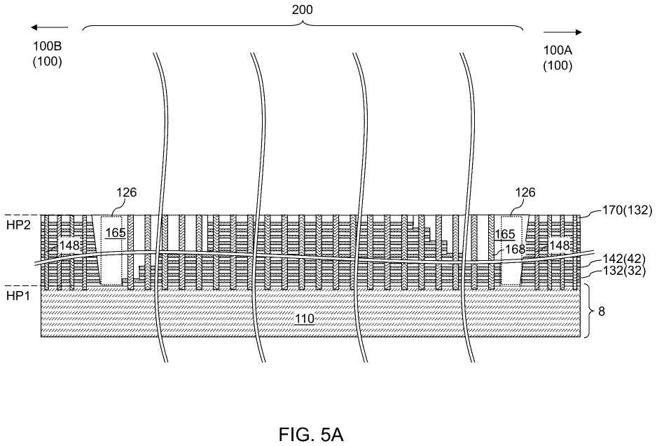

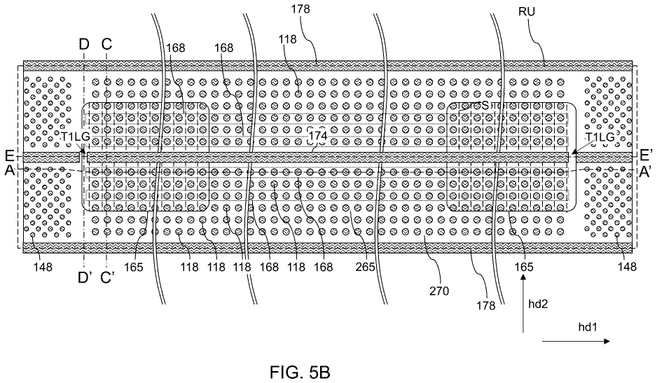

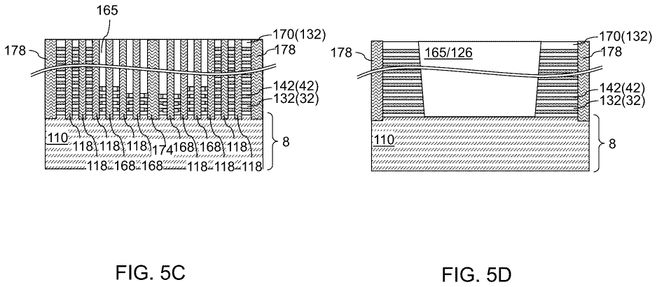

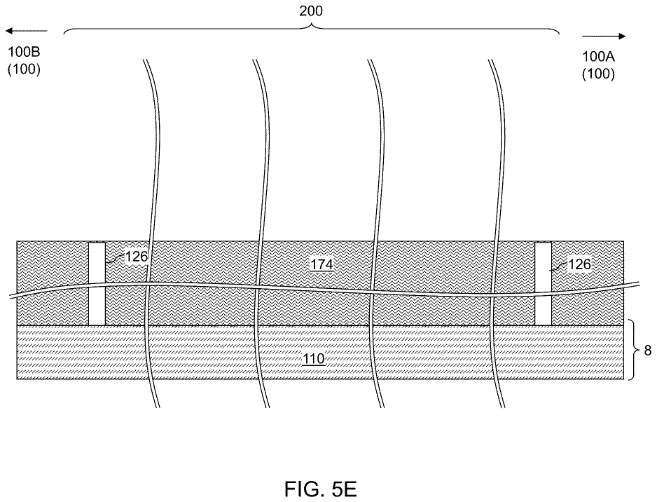

Referring to FIG. 5A-5E, various first-tier openings can be formed through the first-tier structure (132, 142, 165) and into an upper portion of the semiconductor material layer 110. A photoresist layer (not shown) can be applied over the first insulating cap layer 170, and can be lithographically patterned to form various openings therethrough. The pattern of openings in the photoresist layer can be transferred through the first-tier structure (132, 142, 165) and into an upper portion of the semiconductor material layer 110 by a first anisotropic etch process to form the various first-tier openings concurrently. The various first-tier openings can include first-tier memory openings, first-tier support openings, sacrificial first-tier contact openings, and first-tier lateral isolation trenches.

In one embodiment, all first-tier lateral isolation trenches may continuously extend through the inter-array region 200 between the first memory array region 100A and the second memory array region 100B. In another embodiment, odd numbered first-tier lateral isolation trenches may continuously extend through the inter-array region 200 between the first memory array region 100A and the second memory array region 100B, while even numbered first-tier lateral isolation trenches may have gaps formed at locations of the first-tier dielectric separators 126, such that even numbered first-tier lateral isolation trenches may discontinuously extend through the inter-array region 200 between the first memory array region 100A and the second memory array region 100B. In this embodiment, portions of the even numbered first-tier lateral isolation trenches are laterally spaced apart from each other along the first horizontal direction hd1 by at least one lateral gap. The at least one lateral gap is herein referred to as at least one first-tier lateral gap T1LG. Each first-tier lateral gap T1LG may be located entirely within the area of a respective first-tier dielectric separator 126. In other words, each laterally neighboring pair of portions of even numbered first-tier lateral isolation trenches may cut into peripheral portions of an intervening first-tier dielectric separator 126 such that the entire area of a first-tier lateral gap T1LG may be located entirely within the intervening first-tier dielectric separator 126. Alternatively, the even numbered trenches may be continuous and the odd numbered trenches may be discontinuous.

The first-tier memory openings are formed in the memory array regions 100 through each layer within the first-tier vertically alternating sequence (132, 142). The first-tier memory openings are subsequently employed to form memory stack structures therein. The first-tier memory openings can be formed in clusters that are laterally spaced apart along the second horizontal direction hd2. Each cluster of first-tier memory openings can be formed as a two-dimensional array of first-tier memory openings.

The first-tier lateral isolation trenches may have a respective rectangular shape that is elongated along the first horizontal direction hd1. The first-tier vertically alternating sequence is divided into a plurality of first alternating stacks (132,142) of respective first insulating layers 132 and respective first sacrificial material layers 142 by the first-tier lateral isolation trenches alone or optionally in combination with the first-tier dielectric separators 126.

In one embodiment, the first-tier lateral isolation trenches may divide a respective first-tier retro-stepped dielectric material portion 165 into two discrete first-tier retro-stepped dielectric material portions 165. In one embodiment, the first-tier dielectric separator 126 parts of the first-tier retro-stepped dielectric material portions 165 are not divided by the first-tier lateral isolation trenches. In one embodiment, the exemplary structure may include a periodic repetition of a unit pattern that is repeated along the second horizontal direction hd2. Each repetition unit RU may comprise a patterned portion of a first-tier retro-stepped dielectric material portion 165. Each repetition unit RU may comprise two first-tier alternating stacks of first insulating layers 132 and first sacrificial material layers 142. The exemplary structure comprise the first-tier alternating stacks (132, 142) that laterally extend along the first horizontal direction hd1 and are laterally spaced apart from each other by the first-tier lateral isolation trenches, or by a combination of the first-tier lateral isolation trenches and the first-tier dielectric separators 126.

The sacrificial first-tier contact openings can be formed through the first-tier retro-stepped dielectric material portions 165 and through a respective horizontally-extending surface segment of the first stepped surfaces. The first-tier support openings can be formed in the inter-array region 200 in areas that are not filled with the sacrificial first-tier contact openings.

A sacrificial fill material can be deposited in the various first-tier openings to form various sacrificial first-tier opening fill structures. The various sacrificial first-tier opening fill structures comprise sacrificial first-tier memory opening fill structures 148 that are formed in the first-tier memory openings, sacrificial first-tier support opening fill structures 118 that are formed in the first-tier support openings, sacrificial first-tier contact opening fill structures 168 that are formed in the first-tier contact openings, and sacrificial first-tier wall structures (174, 178) that are formed in the first-tier lateral isolation trenches. The sacrificial fill material in the various sacrificial first-tier opening fill structures comprises a material that is different from the materials of the first insulating layers 132 and the first sacrificial material layers 142. For example, the sacrificial fill material in the various sacrificial first-tier opening fill structures may comprise a semiconductor material (such as amorphous silicon or silicon-germanium).

According to an aspect of the present disclosure, first-type sacrificial first-tier wall structures (e.g., even numbered complementary structures) 174 are in contact with first-tier retro-stepped dielectric material portions 165, and second-type sacrificial first-tier wall structures (e.g., odd numbered primary structures) 178 do not contact any first-tier retro-stepped dielectric material portions 165. Each of the first-type sacrificial first-tier wall structures 174 is laterally separated into multiple portions along the first horizontal direction hd1 by the first-tier lateral gaps T1LG located in the first-tier dielectric separators 126 in the inter-array region 200. Each of the second-type sacrificial first-tier wall structures 178 extend continuously without lateral gaps from the first memory array region 100A to the second memory array region 100B through the inter-array region 200.

Central portions of the first-type sacrificial first-tier wall structures 174 will be replaced with complementary dielectric wall structures prior to replacement of sacrificial material layers with electrically conductive layers to provide stable structural support to portions of the alternating stacks (including the first-tier alternating stacks (132, 142) that are proximal to the region previously occupied by the first-type sacrificial first-tier wall structures 174. In one embodiment, rows of first-tier contact opening fill structures 168 are located adjacent to the elongated sidewalls of the first-type sacrificial first-tier wall structures 174. Thus, a row of first-tier contact opening fill structures 168 is located between the respective first-type sacrificial first-tier wall structure 174 and a first row of sacrificial first-tier support opening fill structures 118 along the second horizontal direction hd2. Thus, the first-tier contact opening fill structures 168 are located closer to the first-type sacrificial first-tier wall structure 174 than the closest row of sacrificial first-tier support opening fill structures 118 along the second horizontal direction. In another embodiment, the positions of rows of first-tier contact opening fill structures 168 and rows of sacrificial first-tier support opening fill structures 118 may be reversed along the second horizontal direction, and the first-tier support opening fill structures 118 may be located closer to the first-type sacrificial first-tier wall structure 174 than the first-tier contact opening fill structures 168 along the second horizontal direction.

The horizontal plane including the bottommost surfaces of the first-tier alternating stacks (132, 142) is herein referred to as a first horizontal plane HP1. The horizontal plane including the topmost surfaces of the first-tier alternating stacks (132, 142) is herein referred to as a second horizontal plane HP2.

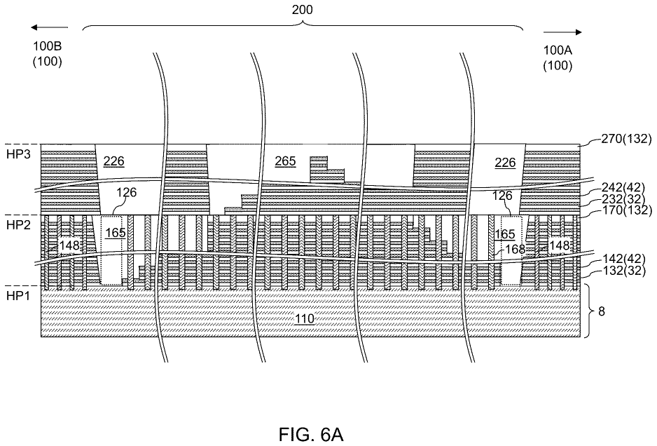

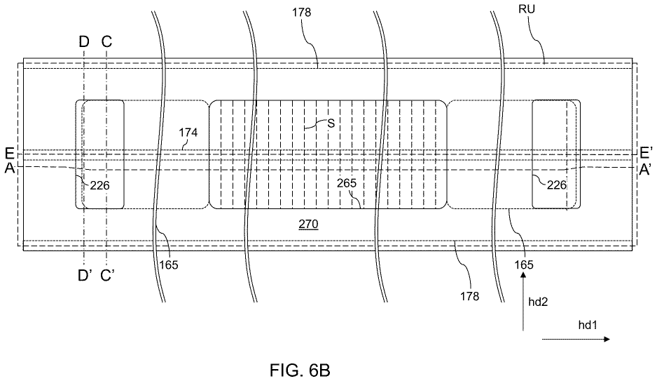

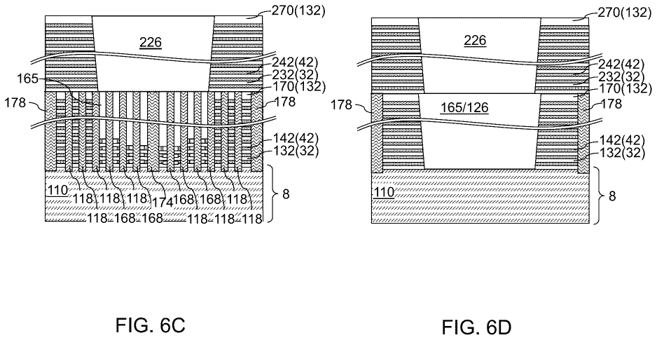

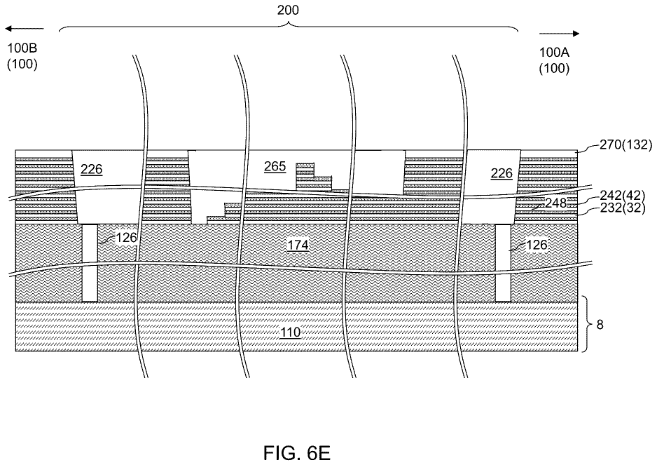

Referring to FIG. 6A-6E, a second-tier vertically alternating sequence of second insulating layers 232 and second sacrificial material layers 242 can be formed over the first-tier structure. Each of the second insulating layers 232 may be formed as a single continuous material layer, and thus, may be referred to as a second continuous insulating layer. Each of the second sacrificial material layers 242 may be formed as a single continuous material layer, and thus, may be formed as a second continuous sacrificial material layer. Each of the second insulating layers 232 and the second sacrificial material layers 242 may have a thickness in a range from 20 nm to 80 nm, although lesser and greater thicknesses may also be employed.

In one embodiment, the second-tier vertically alternating sequence of second insulating layers 232 and second sacrificial material layers 242 may include a periodic repetition of a unit layer stack including a second insulating layer 232 and a second sacrificial material layer 242. The total number of repetitions of the unit layer stack may be in a range from 4 to 1,024, such as from 16 to 256, although lesser and greater numbers of repetitions may also be employed.

The second insulating layers 232 may comprise, and/or may consist essentially of, an insulating material such as undoped silicate glass or a doped silicate glass. The second sacrificial material layers 242 may comprise, and/or may consist essentially of, a sacrificial material such as silicon nitride, a silicon-germanium alloy, organosilicate glass, or a polymer material. Generally, the second sacrificial material layers 242 comprise a material that may be removed selectively to the materials of the second insulating layers 232 and the semiconductor material layer 110. The second insulating layers 232 may comprise the same material as the first insulating layers 132, and the second sacrificial material layers 242 may comprise the same material as the first sacrificial material layers 142. The topmost second insulating layer 232 is herein referred to as a second insulating cap layer 270. The second insulating layers 232 are a second subset of insulating layers 32 that are formed in the exemplary structure. The second sacrificial material layers 242 are a second subset of sacrificial material layers 42 that are formed in the exemplary structure. The topmost surface of the second-tier vertically alternating sequence (232, 242) may be formed in a third horizontal plane HP3.

Second-tier stepped surfaces can be formed by patterning the second-tier vertically alternating sequence (232, 242). In one embodiment, the second-tier stepped surfaces may be formed between areas of the first-tier retro-stepped dielectric material portions 165. For example, the first-tier retro-stepped dielectric material portions 165 may be formed in peripheral portions of the inter-array region 200, and the second-tier stepped surfaces can be formed in a center portion of the inter-array region 200 in each repetition unit RU. Alternatively, if a third-tier structure is to be subsequently formed, an area for subsequently forming third-tier stepped surfaces may be provided within each repetition unit RU.

Generally, the second-tier stepped surfaces may be formed employing any method for forming stepped surfaces as known in the art. For example, a second patterned hard mask layer (not shown) may be formed over the second-tier vertically alternating sequence (232, 242) to define areas in which second-tier stepped surfaces are to be subsequently formed. A second trimmable etch mask layer (not shown) can be formed over the second patterned hard mask layer, and can be lithographically patterned to form slit-shaped openings over peripheral regions of the openings in the second patterned hard mask layer. A unit processing sequence can be repeatedly performed to form second-tier stepped surfaces in the second-tier vertically alternating sequence (232, 242) within the areas of openings in the second patterned hard mask layer. For example, the unit processing sequence may comprise an anisotropic etch process that etches a pair of a second insulating layer 232 and a second sacrificial material layer 242 and a trimming process that isotropically trims the second trimmable etch mask layer. The number of repetitions of the unit processing sequence may be the same as the total number of second sacrificial material layers 242 in the second-tier vertically alternating sequence (232, 242). A second-tier stepped cavity overlying a respective set of second-tier stepped surfaces of the second-tier vertically alternating sequence (232, 242) can be formed within each patterned area of the second-tier vertically alternating sequence (232, 242).

In one embodiment, the vertical steps within each second-tier stepped cavity may be laterally spaced from each other along the first horizontal direction hd1 (which may be a word line direction). In one embodiment, the second-tier stepped cavities may be arranged along a second horizontal direction hd2 (which may be a bit line direction). In one embodiment, the exemplary structure may have a periodic pattern that repeats along the first horizontal direction hd1. Specifically, a repetition unit RU is repeated along the second horizontal direction hd2. In one embodiment, each repetition unit RU may comprise a second-tier stepped cavity. Physically exposed portions of the second continuous sacrificial material layers 242 can be locally thickened underneath the second-tier stepped cavities.

According to an aspect of the present disclosure, each mask pattern in the various etch masks employed to form the second-tier stepped cavities includes additional openings. In one embodiment the additional openings are arranged as a two-dimensional array of openings located at the same locations as the first-tier dielectric separators 126. The pattern of the additional openings in each etch mask pattern may be identical. Thus, the areas of the additional openings in the etch mask patterns are exposed to all anisotropic etch processes that are employed to form the second-tier stepped cavities. Second-tier pillar cavities are formed within the areas of the additional openings in the etch mask patterns. The second-tier pillar cavities have the same depth as the deepest portion of the second-tier stepped cavities. Thus, the second-tier pillar cavities may have a uniform depth that equals the vertical distance between the second horizontal plane HP2 and the third horizontal plane HP3. The maximum depth of each second-tier stepped cavity may be equal to the vertical distance between the second horizontal plane HP2 and the third horizontal plane HP3. In other words, the second-tier pillar cavities may extend through all layers of the second tier.

Each of the second-tier pillar cavities may be aligned to, and may have an areal overlap with, a respective pair of underlying first-tier dielectric separators 126 and the underlying first-type sacrificial first-tier wall structure 174 in the inter-array region 200. In one embodiment, top surface segments of each of the first-type sacrificial first-tier wall structures 174 may be physically exposed underneath a respective subset of the second-tier pillar cavities. The second-type sacrificial first-tier wall structures 178 are not exposed to any second-tier pillar cavity.

The processing steps described with reference to FIGS. 2A-3E may be performed to locally thicken the physically exposed horizontally-extending portions of the second continuous sacrificial material layers 242. Physically exposed vertically extending surfaces of the second continuous sacrificial material layers 242 around the second-tier pillar cavities are not thickened during the local thickening of the physically exposed horizontally extending portions of the second continuous sacrificial material layers 242 due to the mechanisms described with reference to FIGS. 2A-3E.

A dielectric fill material can be deposited within each of the second-tier stepped cavities and in the second-tier pillar cavities. Excess portions of the dielectric fill material can be removed from above the third horizontal plane HP3 by performing a planarization process, which may comprise a chemical mechanical polishing process or a recess etch process. Each remaining portion of the dielectric fill material that fills a respective second-tier stepped cavity constitutes a second-tier retro-stepped dielectric material portion 265. Each remaining portion of the dielectric fill material that fills a respective one of the second-tier pillar cavities constitutes a dielectric pillar structure 226. A second-tier structure is formed, which comprises the second-tier vertically alternating sequence (232, 242), the second-tier retro-stepped dielectric material portions 265, and the dielectric pillar structures 226.

The horizontal cross-sectional shape of the dielectric pillar structures 226 may be any two-dimensional shape having a closed periphery. For example, the horizontal cross-sectional shapes of the dielectric pillar structures 226 may be a polygon (such as rectangle, a rhombus, a hexagon, etc.), a rounded polygon (i.e., a shape that is derived from a polygon by rounding at least one corner), a circle, an oval, or any other suitable two-dimensional shape. In the illustrated example, the shape of each dielectric pillar structure is a rounded rectangle. Generally, the shapes of the second-tier retro-stepped dielectric material portions 265 and the dielectric pillar structures 226 are selected such that the second-tier vertically alternating stack (232, 242) is not completely cut along the second horizontal direction.

In the illustrated example, a second-tier retro-stepped dielectric material portion 265 is formed in a center portion of the inter-tier array region 200 within each repetition unit RU, and a pair of dielectric pillar structures 226 is formed in peripheral portions of the inter-tier array region 200 within each repetition unit RU. The pair of dielectric pillar structures 226 comprises a first dielectric pillar structure 226 that is proximal to the first memory array region 100A and a second dielectric pillar structure 226 that is proximal to the second memory array region 100B.

In one embodiment, each first dielectric pillar structure 226 is formed over the respective first-tier dielectric separator 126. In this embodiment, each first dielectric pillar structure 226 contacts top surfaces of the first-tier dielectric separator 126 which comprises a part of a respective first-tier retro-stepped dielectric material portion 165. In an alternative embodiment, the first-tier dielectric separators 126 may be formed separately from first-tier retro-stepped dielectric material portion 165. In this alternative embodiment, the first-tier dielectric separators 126 may be laterally offset form the first-tier retro-stepped dielectric material portion 165 along the first horizontal direction hd1. Thus, in the alternative embodiment, the first-tier dielectric separators 126 may have the same or similar shape as the first dielectric pillar structures 226.

In one embodiment, bottom surfaces of the first-tier alternating stacks (132, 142) are formed within a first horizontal plane HP1, bottom surfaces of the second-tier alternating stacks (232, 242) are formed within a second horizontal plane HP2, and top surfaces of the second-tier alternating stacks (232, 242) are formed within a third horizontal plane HP3. At least one dielectric pillar structure 226 is formed within each repetition unit RU. In one embodiment, an entire bottom surface of each of the at least one dielectric pillar structure 226 is formed within the second horizontal plane HP2, and an entire top surface of each of the at least one dielectric pillar structure 226 is formed within the third horizontal plane HP3.

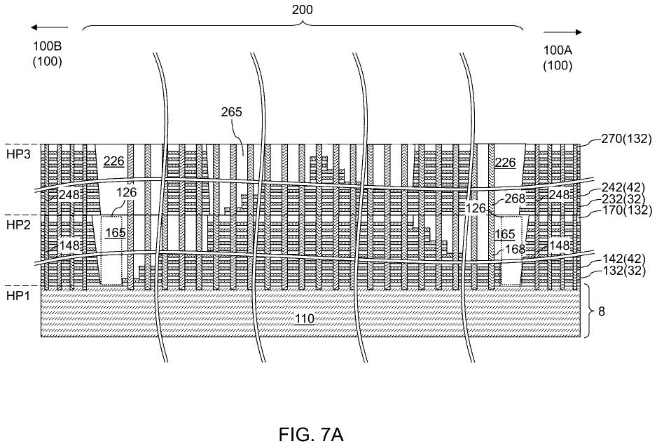

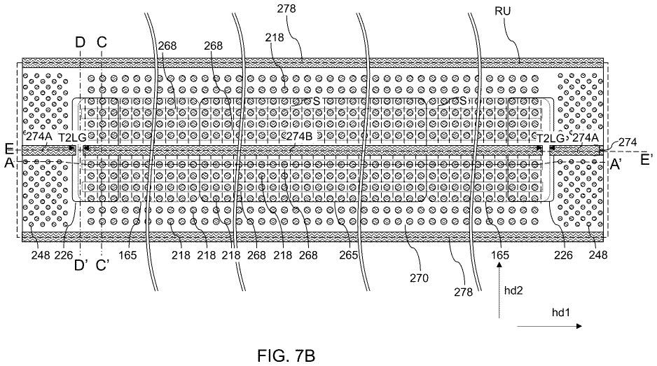

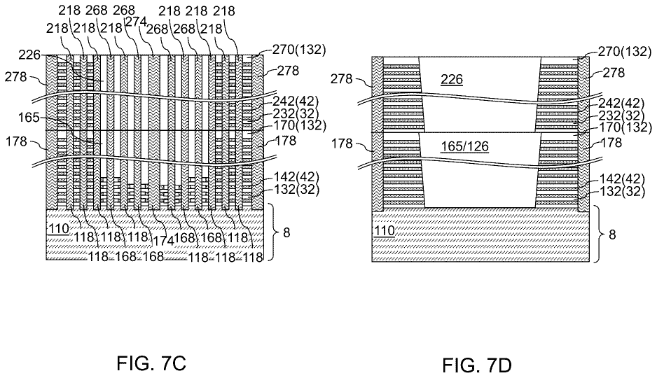

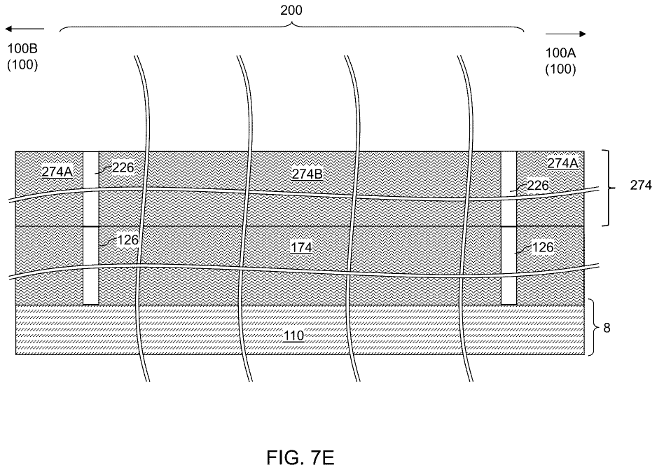

Referring to FIG. 7A-7E, various second-tier openings can be formed through the second-tier structure (232, 242, 265). A photoresist layer (not shown) can be applied over the second insulating cap layer 270, and can be lithographically patterned to form various openings therethrough. The pattern of openings in the photoresist layer can be transferred through the second-tier structure (232, 242, 265) by a second anisotropic etch process to form the various second-tier openings concurrently. The various second-tier openings can include second-tier memory openings, second-tier support openings, sacrificial second-tier contact openings, and second-tier lateral isolation trenches.

The second-tier memory openings are formed in the memory array regions 100 through each layer within the second-tier vertically alternating sequence (232, 242). The second-tier memory openings are subsequently employed to form memory stack structures therein. The second-tier memory openings can be formed in clusters that are laterally spaced apart along the second horizontal direction hd2. Each cluster of second-tier memory openings can be formed as a two-dimensional array of second-tier memory openings. In one embodiment, each second-tier memory opening may be aligned to a respective sacrificial first-tier memory opening fill structure 148.

The second-tier lateral isolation trenches may have a respective rectangular shape that is elongated along the first horizontal direction hd1. According to an aspect of the present disclosure, first-type second-tier lateral isolation trenches may be aligned to and may have an areal overlap with a respective underlying first-type sacrificial first-tier wall structure 174 and the first-tier dielectric separators 126. Second-type second-tier lateral isolation trenches may be aligned to and may have an areal overlap with a respective underlying second-type sacrificial first-tier wall structure 178. According to an aspect of the present disclosure, each of the second-tier lateral isolation trenches may be formed entirely within the area of a respective underlying sacrificial first-tier wall structure (174, 178) and the first-tier dielectric separators 126. The areas of the second-tier lateral isolation trenches can be selected such that the second-type second-tier lateral isolation trenches and the combination of the first-type second-tier lateral isolation trenches and the dielectric pillar structures 226 divide the second-tier vertically alternating sequence (232, 242) of second continuous insulating layers 232 and second continuous sacrificial material layers 242 into a plurality of second-tier alternating stacks (232, 242) of second insulating layers 232 and second sacrificial material layers 242.

In one embodiment, a respective row of multiple first-type second-tier lateral isolation trenches may be formed entirely within the area of the first-type sacrificial first-tier wall structure 174 in a plan view (such as a top-down view). The multiple first-type second-tier lateral isolation trenches are aligned along the second horizontal direction hd2, and are laterally spaced apart from each other by at least one lateral gap, which is herein referred to as at least one second-tier lateral gap T2LG. Each second-tier lateral gap T2LG may be located entirely within the area of a respective dielectric pillar structure 226. In other words, each laterally neighboring pair of first-type second-tier lateral isolation trenches may cut into peripheral portions of an intervening dielectric pillar structure 226 along the first horizontal direction hd1 such that the entire area of a second-tier lateral gap T2LG may be located entirely within the intervening dielectric pillar structure 226.

In one embodiment shown in FIG. 7B, each second-tier lateral isolation trench may comprise a pair of lengthwise sidewalls that are parallel to the first horizontal direction hd1, and a pair of end walls that are parallel to the second horizontal direction hd2. In one embodiment, for each laterally neighboring pair of first-type second-tier lateral isolation trenches laterally separated along the first horizontal direction hd1 by an intervening dielectric pillar structure 226, end portions of each lengthwise sidewall of the laterally neighboring pair of first-type second-tier lateral isolation trenches and two end walls of the laterally neighboring pair of the first-type second-tier lateral isolation trenches are defined by straight sidewalls of the intervening dielectric pillar structure 226. In other words, the ends of the first-type second-tier lateral isolation trenches cut into a pair of dielectric pillar structures 226, such that the walls of the ends of the trenches comprise sidewalls of the dielectric pillar structure 226 exposed in the trenches.

In one embodiment, each second-tier alternating stack (232, 242) of second insulating layers 232 and second sacrificial material layers 242 may be laterally bounded by a second-type second-tier lateral isolation trench that laterally extends through the first memory array region 100A, the inter-array region 200, and the second memory array region 100B on one side, and by a laterally alternating sequence of a plurality of first-type second-tier lateral isolation trenches interlaced with at least one dielectric pillar structure 226 on the other side. In one embodiment, the laterally alternating sequence of the plurality of first-type second-tier lateral isolation trenches interlaced with the at least one dielectric pillar structure 226 may comprise a laterally alternating sequence of the plurality of first-type second-tier lateral isolation trenches interlaced with a plurality of dielectric pillar structure 226. Each second-tier alternating stack (232, 242) continuously extends from the first memory array region 100A through the inter-array region 200 to the second memory array region 100B as a single continuous structure.

The sacrificial second-tier contact openings can be formed through the second-tier retro-stepped dielectric material portions 265 and through a respective horizontally-extending surface segment of the second stepped surfaces. The second-tier support openings can be formed in the inter-array region 200 in areas that are not filled with the sacrificial second-tier contact openings.

A sacrificial fill material can be deposited in the various second-tier openings to form various sacrificial second-tier opening fill structures. The various sacrificial second-tier opening fill structures comprise sacrificial second-tier memory opening fill structures 248 that are formed in the second-tier memory openings, sacrificial second-tier support opening fill structures 218 that are formed in the second-tier support openings, sacrificial second-tier contact opening fill structures 268 that are formed in the second-tier contact openings, and sacrificial second-tier wall structures (278, 274) that are formed in the second-tier lateral isolation trenches. The sacrificial fill material in the various sacrificial second-tier opening fill structures comprises a material that is different from the materials of the second insulating layers 232 and the second sacrificial material layers 242. For example, the sacrificial fill material in the various sacrificial second-tier opening fill structures may comprise a semiconductor material (such as amorphous silicon or silicon-germanium).

Each sacrificial second-tier memory opening fill structure 248 may be formed on a top surface of, may be aligned to, and may have an areal overlap in the plan view with a respective sacrificial first-tier memory opening fill structure 148. Each sacrificial second-tier support opening fill structure 218 may be formed on a top surface of, may be aligned to, and may have an areal overlap in the plan view with a respective sacrificial first-tier support opening fill structure 118. Each sacrificial second-tier contact opening fill structure 268 may be formed on a top surface of, may be aligned to, and may have an areal overlap in the plan view with a respective sacrificial first-tier contact opening fill structure 168. Each sacrificial second-tier wall structure (274, 278) may be formed on a top surface of, may be aligned to, and may have an areal overlap in the plan view, with a respective sacrificial first-tier wall structure (174, 178).

According to an aspect of the present disclosure, the sacrificial second-tier wall structures (274, 278) comprise first-type sacrificial second-tier wall structures 274 and second-type sacrificial second-tier wall structures 278. The first-type sacrificial second-tier wall structures 274 fill the respective first-type second-tier lateral isolation trenches. The second-type of sacrificial second-tier wall structures 278 fill the respective second-type second-tier lateral isolation trenches. The second-type of sacrificial second-tier wall structures 278 continuously extend through the first memory array region 100A, the second memory array region 100B and the inter-array region 200.

The first-type sacrificial second-tier wall structures 274 comprise primary sacrificial second-tier wall structures 274A and complementary sacrificial second-tier wall structure 274B. In one embodiment, each primary sacrificial second-tier wall structure 274A laterally extends through the entirety of a respective one of first memory array region 100A and the second memory array region 100B, and laterally protrudes into a peripheral portion of the inter-array region 200. Each complementary sacrificial second-tier wall structure 274B may be located between and may be aligned along the second horizontal direction hd2 to a respective first primary sacrificial second-tier wall structure 274A located in the first memory array region 100A and a respective second primary sacrificial second-tier wall structure 274A located in the second memory array region 100B. Each complementary sacrificial second-tier wall structure 274B may be laterally spaced from the respective first primary sacrificial second-tier wall structure 274A by a first second-tier lateral gap T2LG, and may be laterally spaced from the respective second primary sacrificial second-tier wall structure 274A by a second second-tier lateral gap T2LG.

The exemplary structure comprises multi-tier layer stacks {(132, 142), (232, 242)} laterally extending along a first horizontal direction hd1 and laterally spaced apart from each other along a second horizontal direction hd2 by lateral spacer structures (174, 178, 126, 278, 274, 226). Each of the multi-tier layer stacks {(132, 142), (232, 242)} comprises a first-tier alternating stack (132, 142) of first insulating layers 132 and first sacrificial material layers 142, and further comprises a second-tier alternating stack (232, 242) of second insulating layers 232 and second sacrificial material layers 242 that overlies the first-tier alternating stack (132, 142). The exemplary structure comprises a first memory array region 100A and a second memory array region 100B that are laterally spaced apart from each other along the first horizontal direction hd1 by an inter-array region 200. All layers within each multi-tier alternating stack of the multi-tier layer stacks {(132, 142), (232, 242)} are present in the first memory array region 100A and in the second memory array region 100B. Each multi-tier alternating stack of the multi-tier layer stacks {(132, 142), (232, 242)} comprises a respective set of stepped surfaces in the inter-array region 200.

In one embodiment, a first-type lateral spacer structure (174, 126, 274, 226) of the lateral spacer structures (174, 178, 126, 278, 274, 226) comprises a combination of a first-type sacrificial first-tier wall structure 174 and two first-tier dielectric separators 126, two primary sacrificial second-tier wall structures 274A, a complementary sacrificial second-tier wall structure 274B, and at least one dielectric pillar structure 226. In one embodiment, a second-type lateral spacer structure (178, 278) of the lateral spacer structures (174, 178, 126, 278, 274, 226) comprises a combination of a second-type sacrificial first-tier wall structure 178 and an overlying second-type sacrificial second-tier wall structure 278.

Each second-type sacrificial first-tier wall structure 178 continuously extends from the first memory array region 100A to the second memory array region 100B through the inter-array region 200 at a first-tier level of the first-tier alternating stacks (132, 142) within the multi-tier layer stacks {(132, 142), (232, 242)}. Each second-type sacrificial second-tier wall structure 278 continuously extends from the first memory array region 100A to the second memory array region 100B through the inter-array region 200 at a second-tier level of the first-tier alternating stacks (232, 242) within the multi-tier layer stacks {(132, 142), (232, 242)}. Each complementary sacrificial second-tier wall structure 274B may be laterally spaced from a respective pair of primary sacrificial second-tier wall structures 274A by a pair of second-tier lateral gaps T2LG at a second-tier level of the second-tier alternating stacks (232, 242). Each of the dielectric pillar structures 226 may be located in the respective second-tier lateral gap T2LG.

In one embodiment, each lateral spacer structure (174, 178, 126, 278, 274, 226) provides a continuous dielectric barrier throughout the first memory array region 100A, the second memory array region 100B, and the inter-array region 200 between a neighboring pair of a first multi-tier layer stack {(132, 142), (232, 242)} and a second multi-tier layer stack {(132, 142), (232, 242)}. In one embodiment, each first-type lateral spacer structure (174, 126, 274, 226) may comprise at least one dielectric pillar structure 226. In one embodiment, each dielectric pillar structure 226 has a greater width along the second horizontal direction hd2 than the sacrificial first-tier wall structures (174, 178) and the sacrificial second-tier wall structures (274, 278) in the respective lateral spacer structure.

In one embodiment, each dielectric pillar structure 226 overlies a neighboring pair of first-tier alternating stacks (132, 142) within a neighboring pair of multi-tier layer stacks {(132, 142), (232, 242)}. In one embodiment, first-tier retro-stepped dielectric material portions 165 may be embedded within a respective one of the first-tier alternating stacks (132, 142).

In one embodiment, bottommost surfaces of the first-tier alternating stacks (132, 142) are located in a first horizontal plane HP1, and bottommost surfaces of the second-tier alternating stacks (232, 242) are located in a second horizontal plane HP2. In one embodiment, top surfaces of the second-tier alternating stacks (232, 242) are located in a third horizontal plane HP3, and each of the at least one dielectric pillar structure 226) has a respective top surface located in the third horizontal plane HP3.

In one embodiment, each second-type sacrificial first-tier wall structure 178 can be located between the first horizontal plane HP1 and the second horizontal plane HP2, and can continuously extend between the first memory array region 100A and the second memory array region 100B through the inter-array region 200 without any gap therein. In one embodiment, a set of first-type sacrificial second-tier wall structures 274 (i.e., 274A and 274B) can overlie a single sacrificial first-type first-tier wall structure 174, can be located entirely between the second horizontal plane HP2 and a third horizontal plane HP3, and can be laterally spaced apart from each other by the at least one second-tier lateral gap T2LG. In one embodiment, each of the at least one second-tier lateral gap T2LG vertically extends from the second horizontal plane HP2 to the third horizontal plane HP3.

In one embodiment, each dielectric pillar structure 226 contacts end segments of lengthwise sidewalls and an end wall of a primary sacrificial second-tier wall structure 274A, and contacts end segments of lengthwise sidewalls and an end wall of a complementary sacrificial second-tier wall structure 274B. The lengthwise sidewalls of each of the sacrificial second-tier wall structures (274, 278) are parallel to the first horizontal direction hd1, and the end walls of each of the sacrificial second-tier wall structures (274, 278) are parallel to the second horizontal direction hd2. All sidewalls of each dielectric pillar structure 226 vertically extend straight without any lateral step between a horizontal plane including bottommost surfaces of the second-tier alternating stacks (232, 242) and a horizontal plane including topmost surfaces of the second-tier alternating stacks (232, 242).

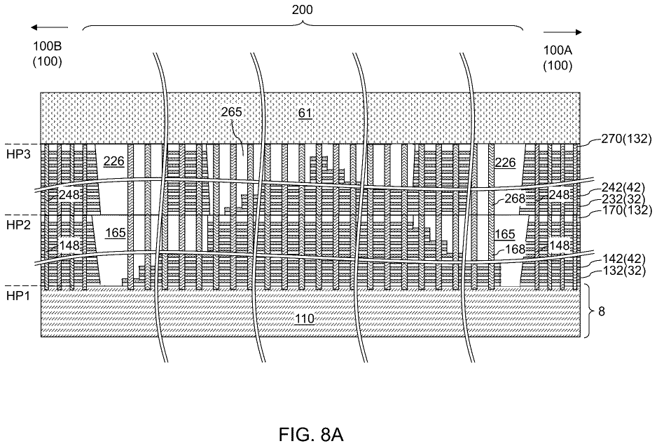

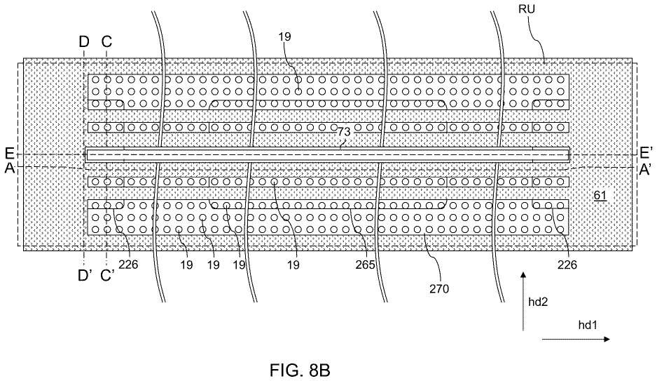

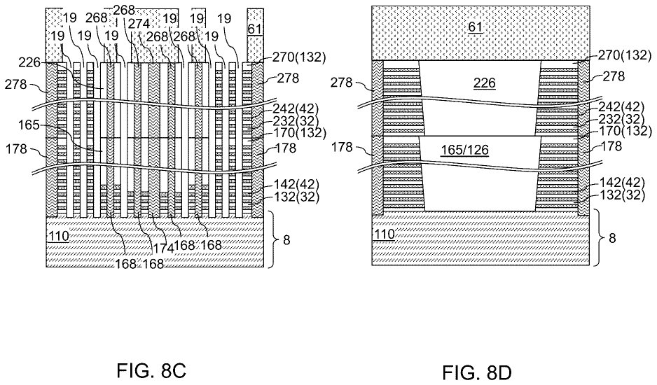

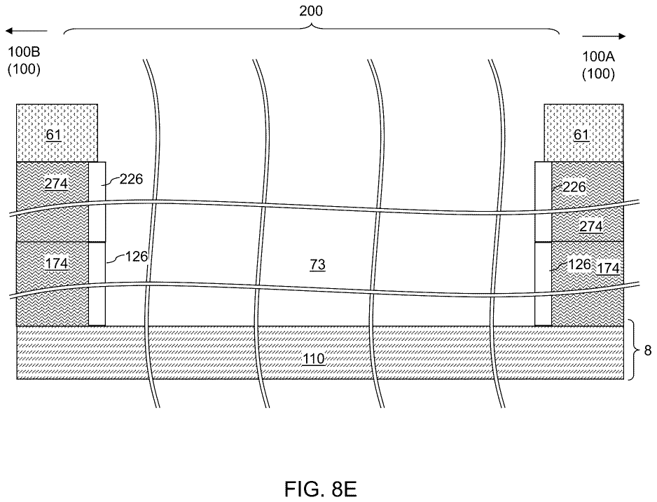

Referring to FIG. 8A-8E, a photoresist layer 61 can be applied over the multi-tier layer stacks {(132, 142), (232, 242)} and the lateral spacer structures (174, 178, 126, 278, 274, 226), and can be lithographically patterned to form openings over the areas of the complementary sacrificial second-tier wall structures 274B and the sacrificial second-tier support opening fill structures 218, while covering all other sacrificial fill material portions. An anisotropic etch process can be performed to etch the complementary sacrificial second-tier wall structures 274B, the sacrificial second-tier support opening fill structures 218, the sacrificial first-tier support opening fill structures 118, and portions of the first-type sacrificial first-tier wall structures 174 that underlie the complementary sacrificial second-tier wall structures 274B selectively to the materials of the dielectric pillar structures 226, the alternating stacks of insulating layers (132, 232) and sacrificial material layers (142, 242) and selectively to the semiconductor material layer 110.

Line cavities 73 are formed in volumes from which the complementary sacrificial second-tier wall structures 274B and underlying portions of the first-type sacrificial first-tier wall structures 174 are removed. Surface segments of the semiconductor material layer 110 can be physically exposed underneath each line cavity 73. The remaining complementary sacrificial second-tier wall structures 274B constitute the first-type sacrificial second-tier wall structures 274.

Inter-tier support openings 19 are formed in volumes from which the sacrificial support opening fill structures (218, 118) are removed. Each of the inter-tier support openings 19 vertically extends through a respective first alternating stack (132, 142) and a respective second alternating stack (232, 242). The inter-tier support openings 19 are formed in the inter-array region 200. The inter-tier support openings 19 may also be referred to as support openings 19. The photoresist layer 61 may then be removed by ashing or another suitable method.

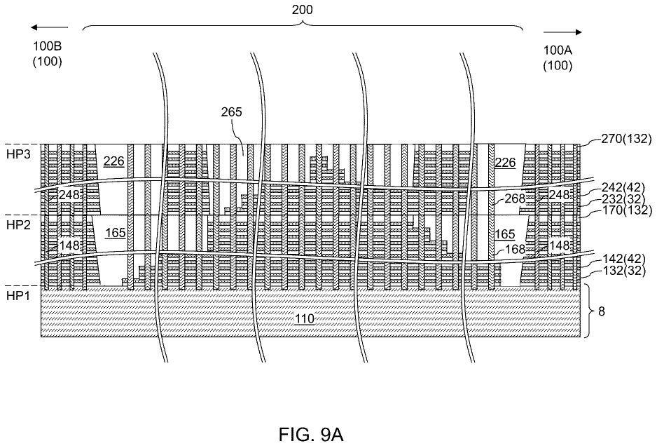

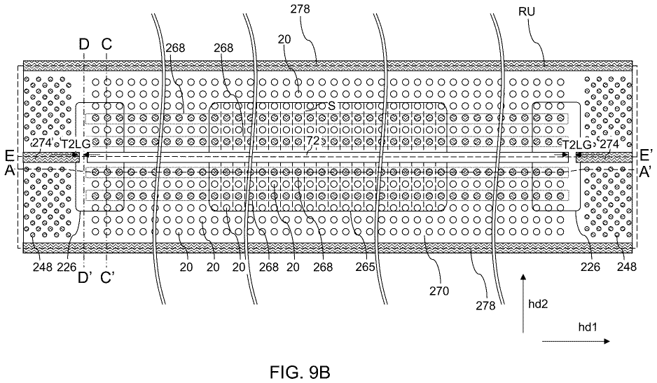

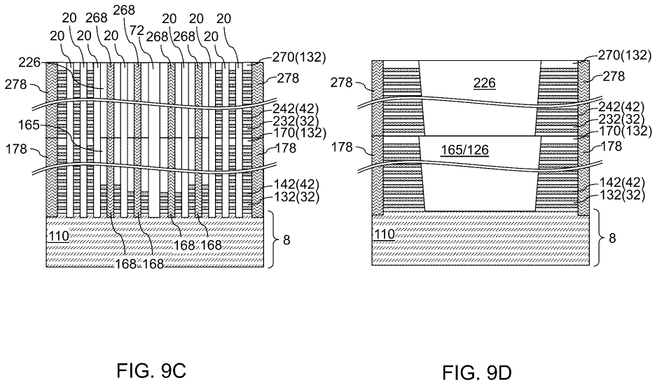

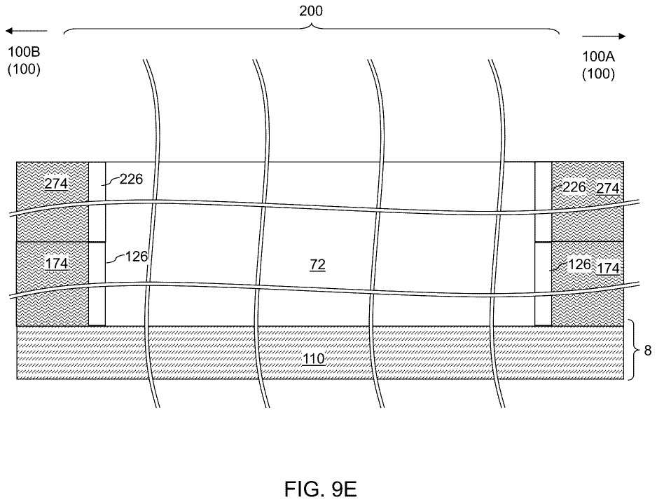

Referring to FIG. 9A-9E, a dielectric fill material can be conformally deposited in the line cavities 73, in the support openings 19, and over the multi-tier layer stacks {(132, 142), (232, 242)} and the lateral spacer structures (174, 178, 126, 278, 274, 226). The dielectric fill material may comprise undoped silicate glass (i.e., silicon oxide) or a doped silicate glass (such as borosilicate glass, borophosphosilicate glass, a carbon-doped silicate glass, etc.). Optionally, a dielectric metal oxide liner (such as an aluminum oxide liner or a dielectric transition metal oxide liner) may be conformally deposited before deposition of the dielectric fill material.

Horizontally-extending portions of the dielectric fill material overlying top surfaces of the multi-tier layer stacks {(132, 142), (232, 242)} may be removed by performing a planarization process. The planarization process may comprise a recess etch process and/or a chemical mechanical polishing process. Each remaining portion of the dielectric fill material that fills a respective support opening 19 constitutes a support pillar structure 20. Each remaining portion of the dielectric fill material that fills a respective line trench 73 constitutes a complementary dielectric wall structure 72.

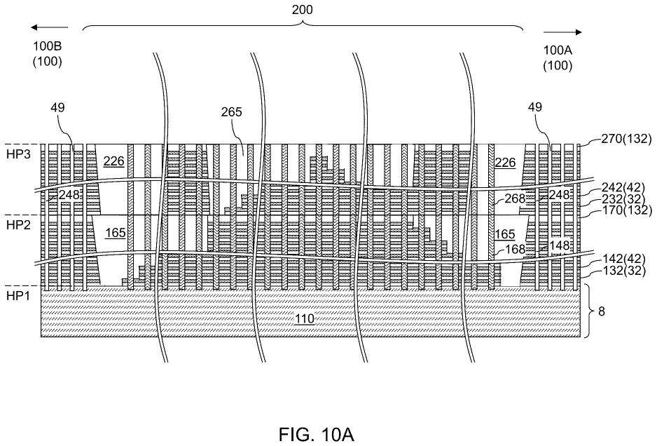

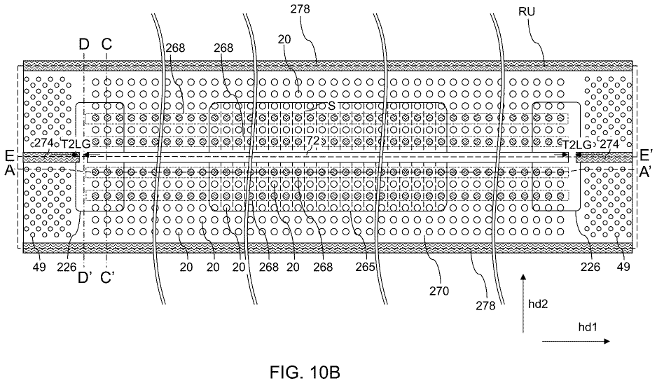

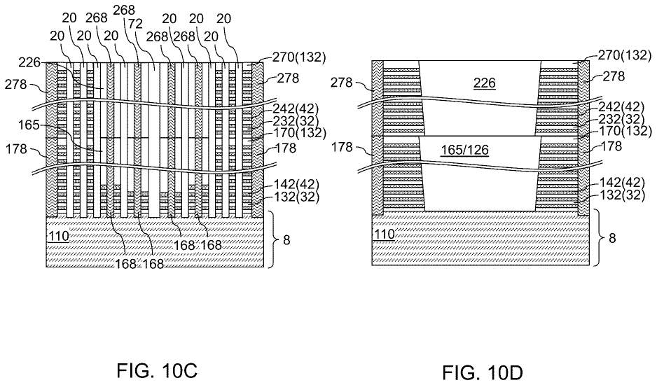

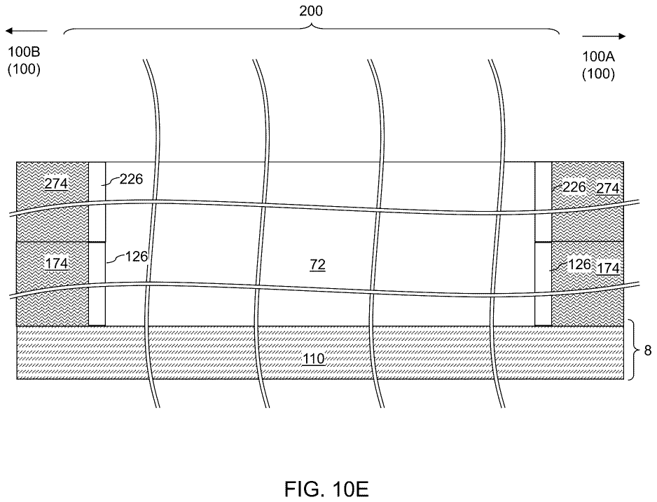

Referring to FIG. 10A-10E, a masking layer, such as a photoresist layer (not shown), can be deposited over the structure of FIG. 9A-9E, and can be patterned to form openings in the areas of the sacrificial second-tier memory opening fill structures 248 and the sacrificial first-tier memory opening fill structures 148 while covering all other sacrificial fill material portions. The sacrificial second-tier memory opening fill structures 248 and the sacrificial first-tier memory opening fill structures 148 are removed selectively to the alternating stacks of insulating layers (132, 232) and sacrificial material layers (142, 242) and selectively to the semiconductor material layer 110. An isotropic etch process or an anisotropic etch process may be performed. Inter-tier memory openings 49 are formed in volumes from which the sacrificial memory opening fill structures (248, 148) are removed. Each of the inter-tier memory openings 49 vertically extends through a respective first alternating stack (132, 142) and a respective second alternating stack (232, 242). The inter-tier memory openings 49 are formed in the memory array regions 100A and 100B. The inter-tier memory openings 49 may also be referred to as memory openings 49. The photoresist layer may then be removed by ashing or another suitable method.

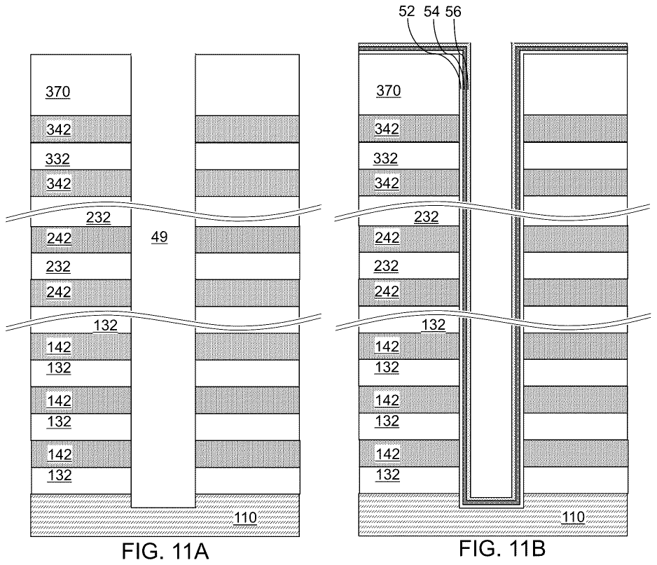

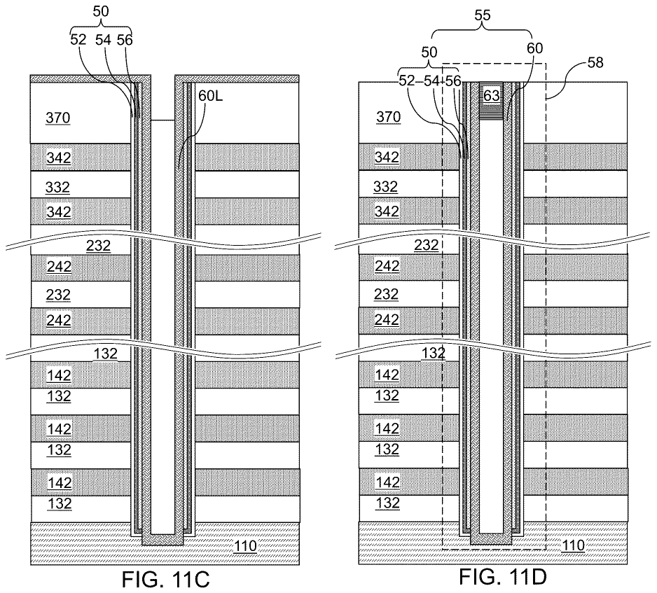

FIG. 11A-11D illustrate sequential vertical cross-sectional views of a memory opening 49 during formation of a memory opening fill structure according to an embodiment of the present disclosure.

Referring to FIG. 11A, a memory opening 49 in the exemplary structure of FIG. 10A-10E is illustrated. The memory opening 49 extends through a first-tier structure and a second-tier structure.

Referring to FIG. 11B, a stack of layers including an optional blocking dielectric layer 52, a memory material layer 54, an optional dielectric liner 56, and a semiconductor channel material layer 60L can be sequentially deposited in the memory openings 49. The blocking dielectric layer 52 can include a single dielectric material layer or a stack of a plurality of dielectric material layers. In one embodiment, the blocking dielectric layer can include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 can include a dielectric metal oxide having a dielectric constant greater than 7.9, i.e., having a dielectric constant greater than the dielectric constant of silicon nitride. The thickness of the dielectric metal oxide layer can be in a range from 1 nm to 20 nm, although lesser and greater thicknesses can also be employed. The dielectric metal oxide layer can subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 can include a dielectric semiconductor compound such as silicon oxide, silicon oxynitride, silicon nitride, or a combination thereof.

Subsequently, the memory material layer 54 can be formed. Generally, the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer.

The optional dielectric liner 56, if present, includes a dielectric material. In case the memory material layer 54 comprises a charge storage material, the dielectric liner 56 comprises a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed. The stack of the blocking dielectric layer 52, the memory material layer 54, and the dielectric liner 56 constitutes a memory film 50 that stores memory bits.

Referring to FIG. 11C, an anisotropic etch process can be performed to remove horizontally-extending portions of the dielectric liner 56, the memory material layer 54, and the blocking dielectric layer 52. Each remaining contiguous combination of an optional blocking dielectric layer 52, a memory material layer 54, and an optional dielectric liner 56 constitutes a memory film 50. A top surface of the semiconductor material layer 110 can be physically exposed at the bottom of each memory opening 49.

A semiconductor channel material layer 60L can be conformally deposited over the memory film 50 within each memory opening 49. The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L includes amorphous silicon or polysilicon. The semiconductor channel material layer 60L can be formed by a conformal deposition method such as low pressure chemical vapor deposition (LPCVD). The thickness of the semiconductor channel material layer 60L can be in a range from 2 nm to 10 nm, although lesser and greater thicknesses can also be employed. A cavity may be present in the volume of each memory opening 49 that is not filled with the deposited material layers (52, 54, 56, 60L).

In case the cavity in each memory opening is not completely filled by the semiconductor channel material layer 60L, a dielectric core layer can be deposited in the cavity to fill any remaining portion of the cavity within each memory opening. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. The horizontal portion of the dielectric core layer overlying the second insulating cap layer 270 can be removed, for example, by a recess etch. The recess etch continues until top surfaces of the remaining portions of the dielectric core layer are recessed to a height between the top surface of the second insulating cap layer 270 and the bottom surface of the second insulating cap layer 270. Each remaining portion of the dielectric core layer constitutes a dielectric core 62.

Referring to FIG. 11D, a doped semiconductor material can be deposited in cavities overlying the dielectric cores 62. The doped semiconductor material has a doping of the opposite conductivity type of the doping of the semiconductor channel material layer 60L. Thus, the doped semiconductor material has a doping of the second conductivity type. Portions of the deposited doped semiconductor material, the semiconductor channel material layer 60L, the dielectric liner 56, the memory material layer 54, and the blocking dielectric layer 52 that overlie the horizontal plane including the top surface of the second insulating cap layer 270 can be removed by a planarization process such as a chemical mechanical planarization (CMP) process.

Each remaining portion of the doped semiconductor material having a doping of the second conductivity type constitutes a drain region 63. The drain regions 63 can have a doping of a second conductivity type that is the opposite of the first conductivity type. For example, if the first conductivity type is p-type, the second conductivity type is n-type, and vice versa. The dopant concentration in the drain regions 63 can be in a range from 5.0×10¹⁸/cm³ to 2.0×10²¹/cm³, although lesser and greater dopant concentrations can also be employed. The doped semiconductor material can be, for example, doped polysilicon.

Each remaining portion of the semiconductor channel material layer 60L constitutes a vertical semiconductor channel 60 through which electrical current can flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of laterally-extending cavities. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a dielectric liner 56, a plurality of memory elements embodied as portions of the memory material layer 54, and an optional blocking dielectric layer 52. Each combination of a memory stack structure 55, a dielectric core 62, and a drain region 63 within a memory opening 49 constitutes a memory opening fill structure 58. In one embodiment, top surfaces of the memory opening fill structures 58 may be formed within a horizontal plane including the top surfaces of the multi-tier layer stacks {(132, 142), (232, 242)}. Each of the memory opening fill structures 58 comprises a respective vertical semiconductor channel 60 and respective vertical stack of memory elements, which may comprise portions of the memory material layers 54 located at the levels of the sacrificial material layers (142, 242).

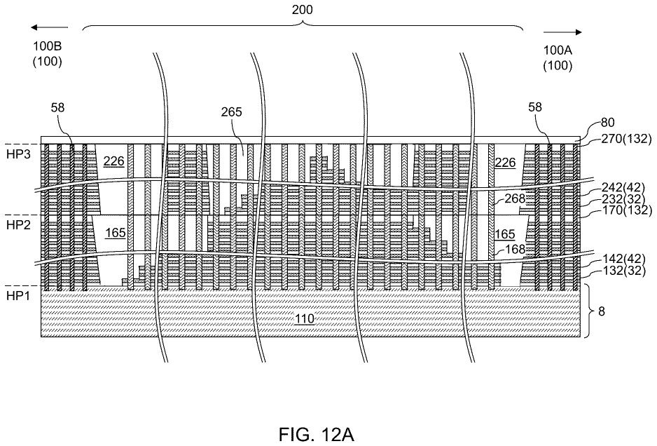

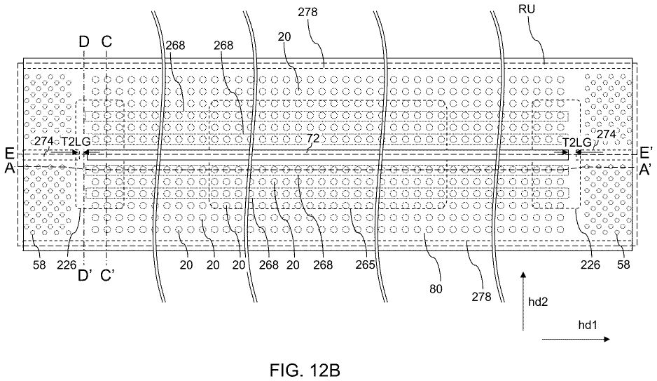

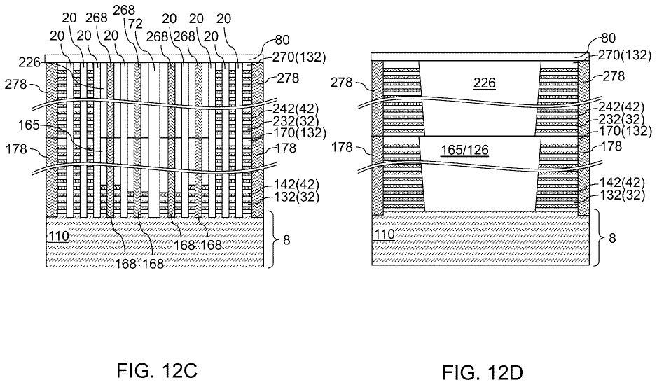

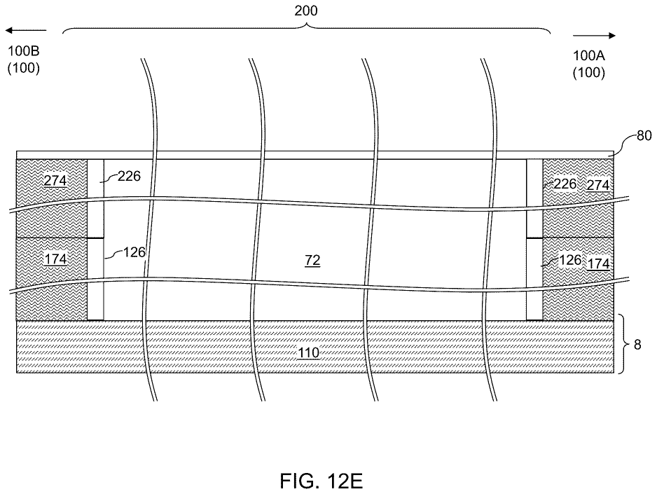

Referring to FIG. 12A-12E, a dielectric material can be deposited over the multi-tier layer stacks {(132, 142), (232, 242)} to form a contact-level dielectric layer 80. The thickness of the contact-level dielectric layer 80 may be in a range from 100 nm to 600 nm, although lesser or greater thicknesses may also be employed. In one embodiment, top surfaces of the support pillar structures 20 may be formed within a horizontal plane including the top surfaces of the multi-tier layer stacks {(132, 142), (232, 242)}.

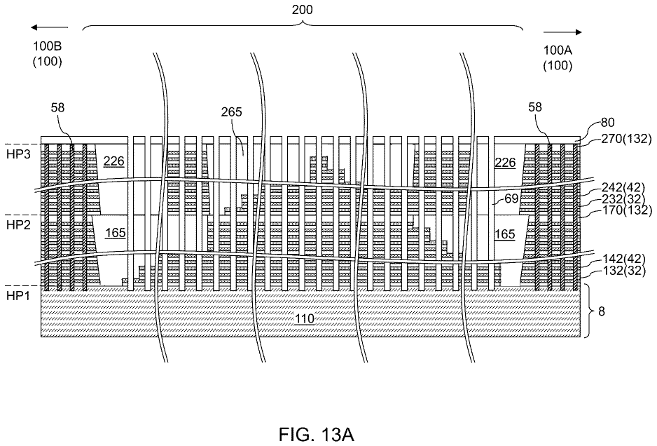

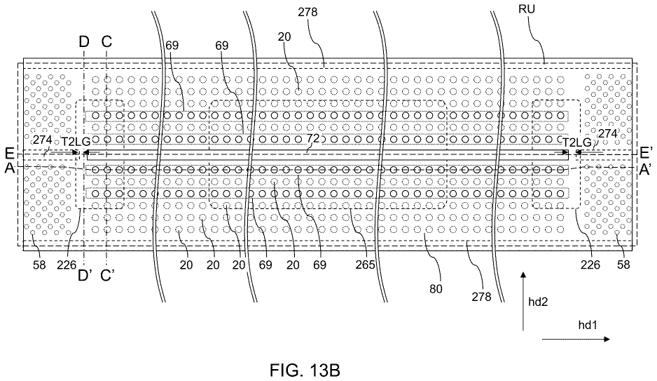

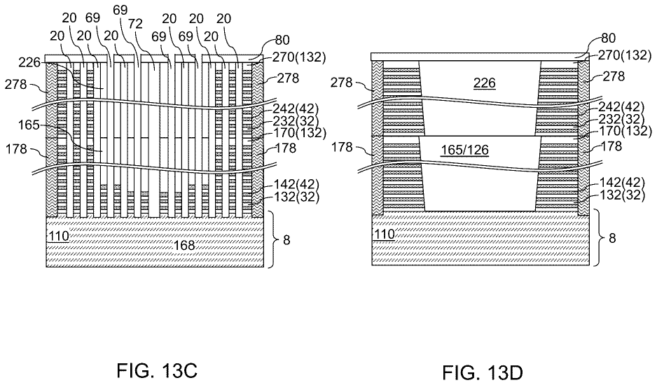

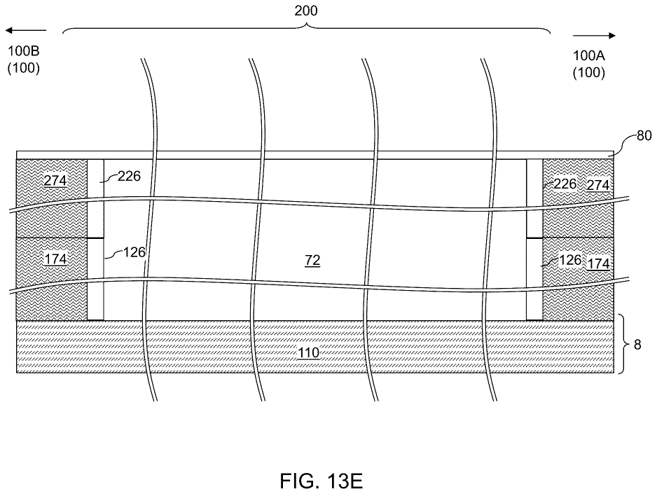

Referring to FIG. 13A-13E, a photoresist layer (not illustrated) can be applied over the contact-level dielectric layer 80, and can be lithographically patterned to form openings over the sacrificial contact openings fill structures (168, 268). An etch process, such as an anisotropic etch process, can be performed to form openings through the contact-level dielectric layer 80 over the sacrificial contact openings fill structures (168, 268).

Subsequently, the sacrificial contact opening fill structures (168, 268) are removed selectively to the alternating stacks of insulating layers (132, 232) and sacrificial material layers (142, 242), and selectively to the semiconductor material layer 110. Inter-tier contact openings 69, which are also referred to as contact openings 69, are formed in volumes from which the sacrificial contact opening fill structures (168, 268) are removed. The photoresist layer can be subsequently removed, for example, by ashing.

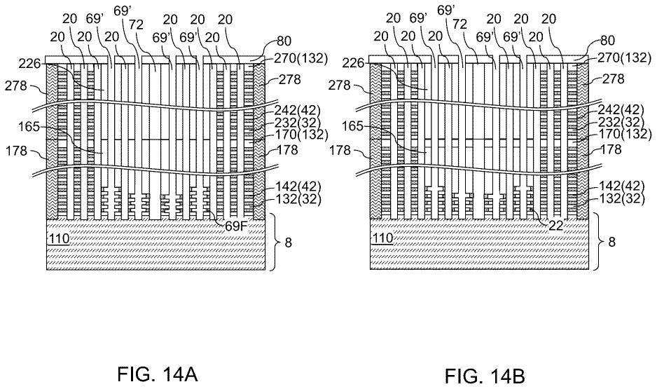

Referring to FIG. 14A, a selective isotropic etch process can be performed to isotropically etch portions of the sacrificial material layers (142, 242) that are proximal to the contact openings 69. Fin-shaped voids 69F are formed around each contact opening 69 at each level of the sacrificial material layers (142, 242). Each contiguous combination of a contact opening 69 and adjoined fin-shaped voids 69F constitutes a finned contact opening 69′.

As discussed above, portions of the continuous sacrificial material layers (142, 242) that are exposed to the first stepped cavities or to the second stepped cavities are locally thickened. Thus, for each set of at least one fin-shaped void 69F within a finned contact opening 69′, a fin-shaped void 69F that immediately underlies a respective retro-stepped dielectric material portion (165, 265) is thicker than any other fin-shaped void 69F.

Referring to FIG. 14B, a dielectric liner layer can be conformally deposited in peripheral regions of the finned contact openings 69′. The dielectric liner layer comprises a dielectric material having a different material composition than the sacrificial material layers (142, 242). For example, the dielectric liner layer may comprise silicon oxide. The thickness of the dielectric liner layer is greater than one half of the thickness of unthickened portions of the sacrificial material layers (142, 242), and is less than one half of the thickness of locally thickened portions of the continuous sacrificial material layers (142, 242). Thus, for each set of at least one fin-shaped void 69F within a finned contact opening 69′, one fin-shaped void 69F that is laterally surrounded by a respective locally thickened portion of the sacrificial material layers (142, 242) is not completely filled within the dielectric liner layer, while any other fin-shaped void 69F (if present) is completely filled with the dielectric liner layer.

An isotropic recess etch process can be performed to isotropically recess portions of the dielectric liner layer that are deposited outside completely filled fin-shaped voids 69F. Each remaining portion of the dielectric liner layer located in a subset of the fin-shaped voids 69F constitutes an annular insulating spacer 22, while the tallest fin-shaped void 69F remains unfilled. For each finned contact opening 69′ comprising two or more fin-shaped voids 69F, one or more annular insulating spacers 22 are formed in the fin-shaped voids 69F except within the tallest fin-shaped void 69F. The tallest fin-shaped void 69F within each finned contact opening 69′ has a greater height than the fin-shaped voids 69F that are filled with the annular insulating spacers 22 due to the local thickening of the physically exposed portions of the sacrificial material layers (142, 242) discussed above. The annular insulating spacers 22 provide lateral electrical isolation between layer contact via structures to be subsequently formed and electrically conductive layers to be subsequently formed.

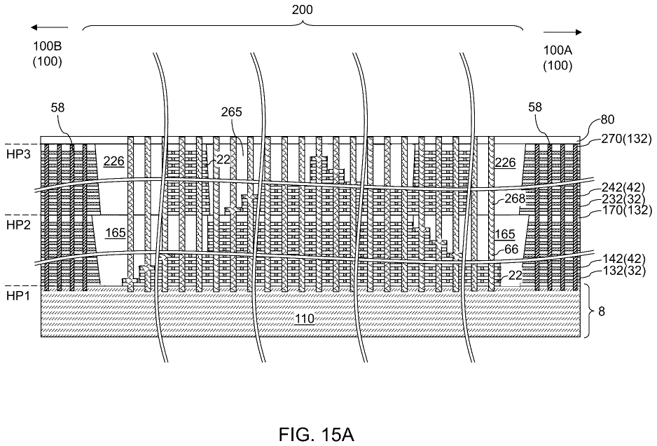

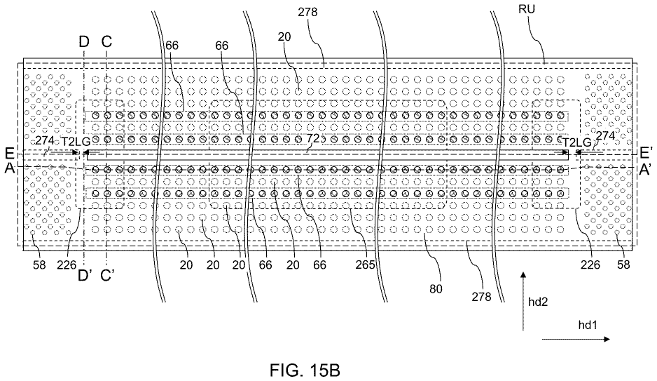

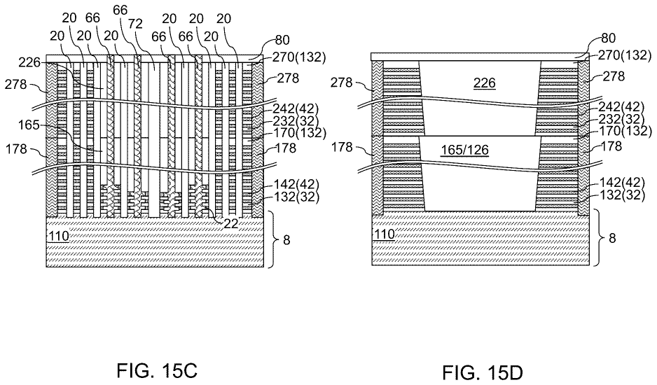

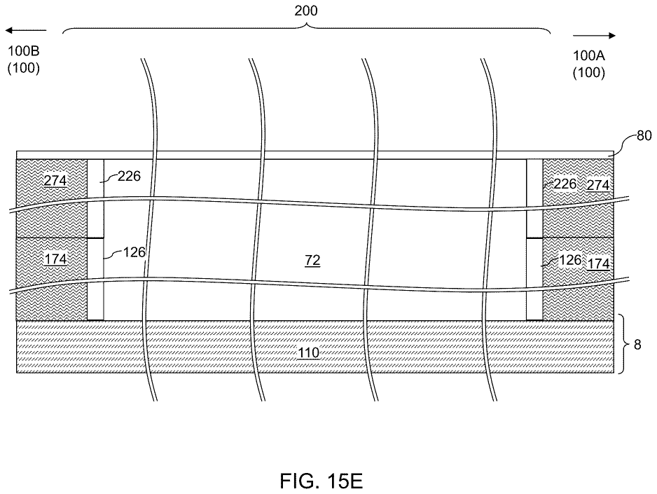

Referring to FIG. 15A-15E, a sacrificial via fill material can be deposited in the finned contact openings 69′, each including a respective unfilled fin-shaped void 69F, to form sacrificial contact via structures 66. The sacrificial contact via structures 66 may comprise a semiconductor material, such as amorphous silicon.

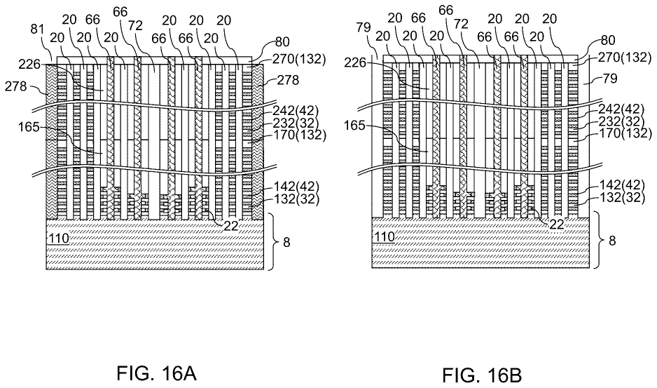

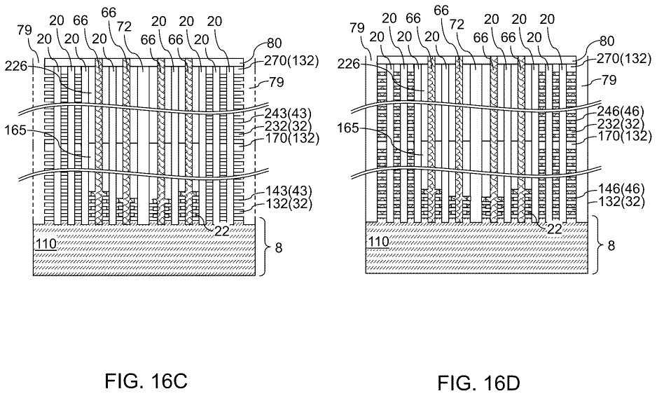

Referring to FIG. 16A, a photoresist layer (not illustrated) can be applied over the contact-level dielectric layer 80, and can be lithographically patterned to form openings over the second-tier sacrificial wall structures (274, 278). In one embodiment, a two-dimensional rectangular array of openings may be formed in the photoresist layer.

Referring to FIG. 16B, the sacrificial second-tier wall structures (274, 278) and the sacrificial first-tier wall structures (174, 178) can be removed selectively to the alternating stacks of insulating layers (132, 232) and sacrificial material layers (142, 242). An isotropic etch process or an anisotropic etch process may be performed. Inter-tier lateral isolation trenches 79, which are also referred to as lateral isolation trenches 79, are formed in volumes from which the primary sacrificial second-tier wall structures (274, 278) and the sacrificial first-tier wall structures (174, 178) are removed. The complementary dielectric wall structure 72, the first-tier dielectric separators 126 and the dielectric pillar structures 226 remain in the first-type lateral isolation trenches 79 which extend through the retro-stepped dielectric material portions (165, 265), and function isolation trench bridges which prevent or reduce tilting or collapse of the alternating stacks into the lateral isolation trenches 79.

Optionally, an oxidation process may be performed to convert physically exposed surface portions of the semiconductor material layer 110 into silicon oxide portions (not illustrated), which can be subsequently employed to protect the semiconductor material layer 110 during subsequent etch processes.

Referring to FIG. 16C, an etchant that selectively etches the materials of the sacrificial material layers (142, 242) with respect to the materials of the insulating layers (132, 232), the contact-level dielectric layer 80, the retro-stepped dielectric material portions (165, 265), and the material of the outermost layer of the memory films 50 can be introduced into the lateral isolation trenches 79, for example, employing an isotropic etch process. For example, the sacrificial material layers (142, 242) can include silicon nitride, the materials of the insulating layers (132, 232), the material of the retro-stepped dielectric material portions (165, 265), and the material of the outermost layer of the memory films 50 can include silicon oxide materials.

The isotropic etch process can be a wet etch process employing a wet etch solution, or can be a gas phase (dry) etch process in which the etchant is introduced in a vapor phase into the lateral isolation trenches 79. For example, if the sacrificial material layers (142, 242) include silicon nitride, the etch process can be a wet etch process in which the exemplary structure is immersed within a wet etch tank including phosphoric acid, which etches silicon nitride selectively to silicon oxide, silicon, and various other materials employed in the art. Laterally-extending cavities 43 (e.g., 143, 243) are formed in the volumes from which the sacrificial material layers 42 (e.g., 142, 242) are removed.

Each of the laterally-extending cavities 43 can be a laterally extending cavity having a lateral dimension that is greater than the vertical extent of the cavity. In other words, the lateral dimension of each of the laterally-extending cavities 43 can be greater than the height of the respective laterally-extending cavity 43. A plurality of first laterally-extending cavities 143 can be formed in the volumes from which the material of the first sacrificial material layers 142 is removed. A plurality of second laterally-extending cavities 243 can be formed in the volumes from which the material of the second sacrificial material layers 242 is removed. Each of the laterally-extending cavities 43 can extend substantially parallel to the top surface of the substrate 8. A laterally-extending cavity 43 can be vertically bounded by a top surface of an underlying insulating layer (132, 232) and a bottom surface of an overlying insulating layer (132, 232). In one embodiment, each of the laterally-extending cavities 43 can have a uniform height throughout.

Referring to FIG. 16D, an outer blocking dielectric layer (not shown) can be optionally deposited in the laterally-extending cavities 43 and the lateral isolation trenches 79 and over the contact-level dielectric layer. At least one conductive material can be deposited in the plurality of laterally-extending cavities 43, on the sidewalls of the lateral isolation trenches 79, and over the contact-level dielectric layer 80. The at least one conductive material can be deposited by a conformal deposition method, which can be, for example, chemical vapor deposition (CVD), atomic layer deposition (ALD), electroless plating, electroplating, or a combination thereof. The at least one conductive material can include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material can include at least one metallic material, i.e., an electrically conductive material that includes at least one metallic element. Non-limiting exemplary metallic materials that can be deposited in the laterally-extending cavities 43 include tungsten, tungsten nitride, titanium, titanium nitride, tantalum, tantalum nitride, cobalt, and ruthenium. For example, the at least one conductive material can include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the laterally-extending cavities 43 can be a combination of titanium nitride layer and a tungsten fill material.

Electrically conductive layers (146, 246) can be formed in the laterally-extending cavities 43 by deposition of the at least one conductive material. A plurality of first electrically conductive layers 146 can be formed in the plurality of first laterally-extending cavities 243, a plurality of second electrically conductive layers 246 can be formed in the plurality of second laterally-extending cavities 243, and a continuous metallic material layer (not shown) can be formed on the sidewalls of each lateral isolation trench 79 and over the contact-level dielectric layer 80. Each of the electrically conductive layers (146, 246) may include a respective conductive metallic nitride liner and a respective conductive fill material. Thus, the sacrificial material layers (142, 242) can be replaced with the electrically conductive layers (146, 246), respectively. Specifically, each first sacrificial material layer 142 can be replaced with an optional portion of the outer blocking dielectric layer and a first electrically conductive layer 146, and each second sacrificial material layer 242 can be replaced with an optional portion of the outer blocking dielectric layer and a second electrically conductive layer 246. A backside cavity is present in the portion of each lateral isolation trench 79 that is not filled with the continuous metallic material layer.

Residual conductive material can be removed from inside the lateral isolation trenches 79. Specifically, the deposited metallic material of the continuous metallic material layer can be etched back from the sidewalls of each lateral isolation trench 79 and from above the contact-level dielectric layer 80, for example, by an isotropic etchback process. Each remaining portion of the deposited metallic material in the first laterally-extending cavities 143 constitutes a first electrically conductive layer 146. Each remaining portion of the deposited metallic material in the second laterally-extending cavities 243 constitutes a second electrically conductive layer 246. The first electrically conducive layers 146 and the second electrically conductive layers 246 are collectively referred to as electrically conductive layers 46. Thus, the sacrificial material layers 42 are replaced with the electrically conductive layers 46.

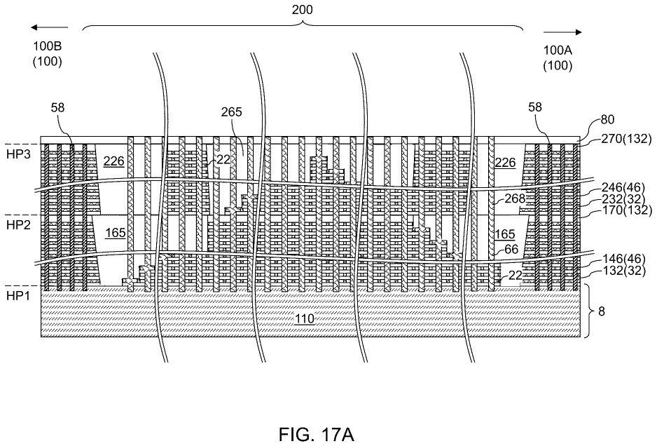

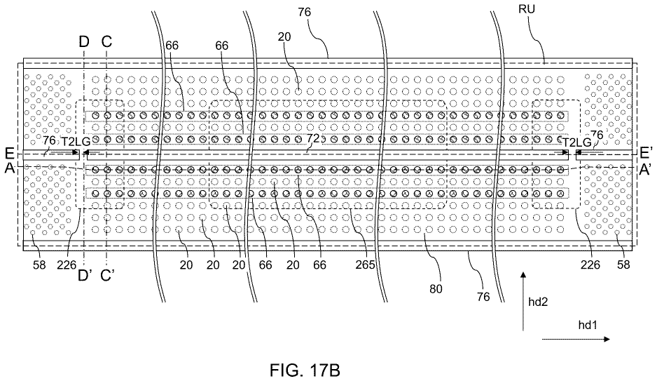

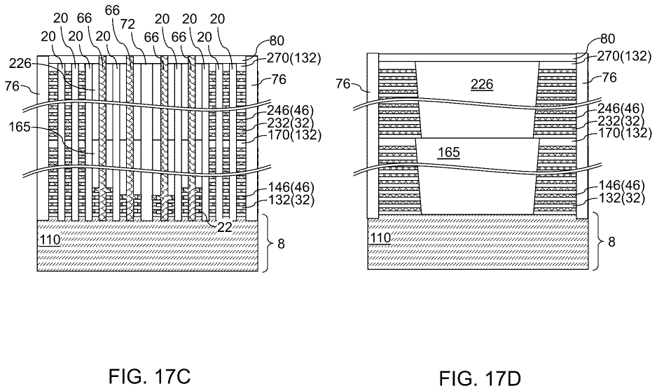

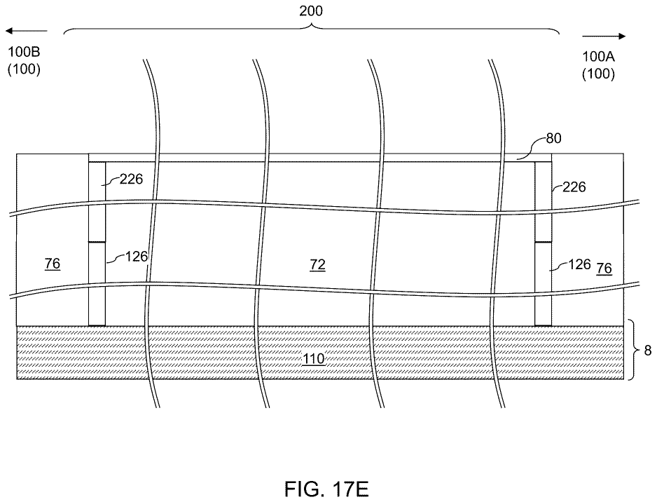

Referring to FIG. 17A-17E, a dielectric fill material, such as undoped silicate glass (i.e., silicon oxide) or a doped silicate glass may be deposited in the lateral isolation trenches 79. The dielectric fill material may be deposited by a conformal deposition process (such as a chemical vapor deposition process) or a self-planarizing deposition process (such as spin-coating). Any excess portion of the dielectric fill material overlying the contact-level dielectric layer 80 may be removed from above the horizontal plane including the top surface of the contact-level dielectric layer 80 by a planarization process (which may comprise a recess etch process or a chemical mechanical polishing process). Remaining portions of the dielectric fill material filling the lateral isolation trenches 79 constitute dielectric wall structures 76. Alternatively, the excess portion of the dielectric fill material overlying the contact-level dielectric layer 80 may be incorporated into the contact-level dielectric layer 80. Generally, top surfaces of the dielectric wall structures 76 may be formed within the horizontal plane including the top surface of the contact-level dielectric layer 80.

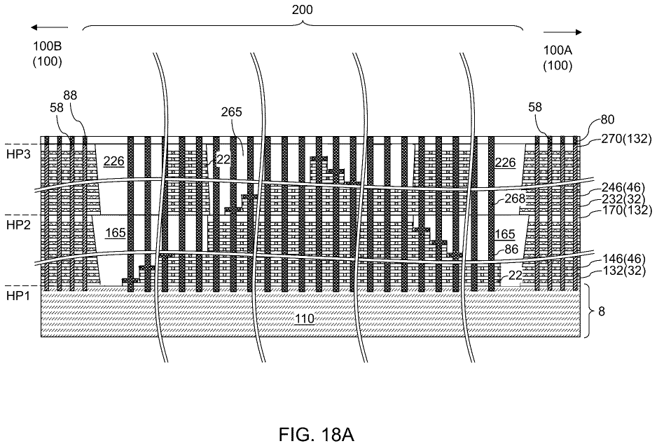

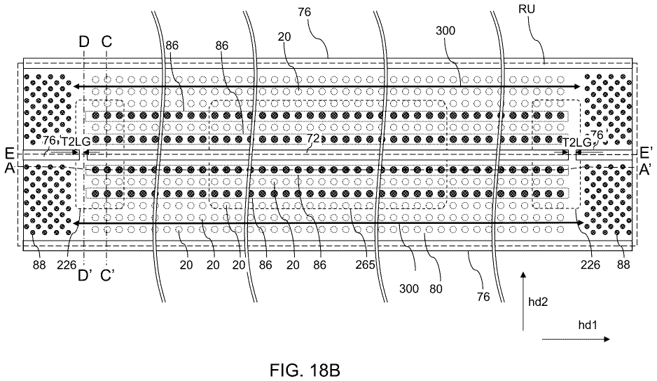

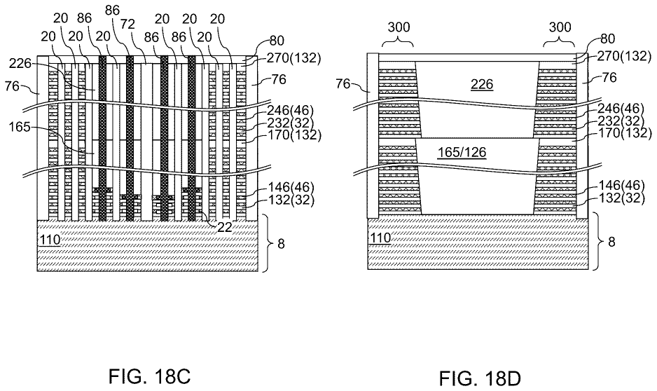

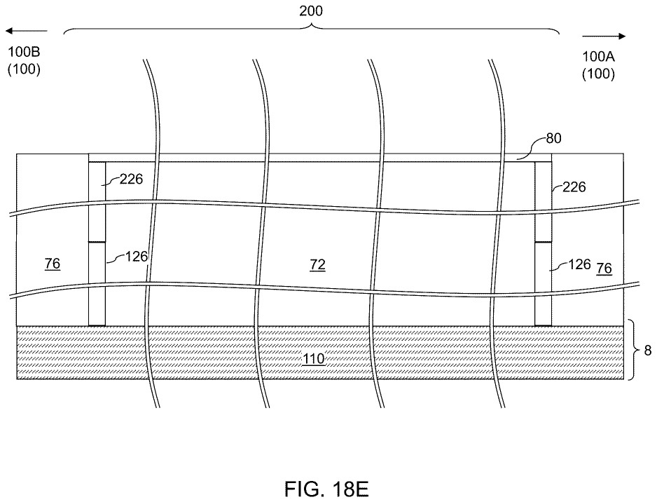

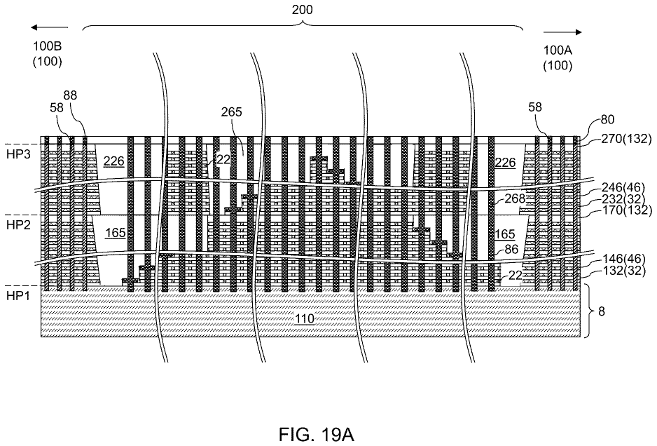

Referring to FIG. 18A-18E, a selective etch process may be performed to remove sacrificial contact via structures 66 selective to the materials of the contact-level dielectric layer 80, the retro-stepped dielectric material portions (165, 265), the insulating layers 32, and the electrically conductive layers 46. Through-via cavities can be formed in the volumes from which the sacrificial contact via structures 66 are removed. An isotropic etch process may be performed to remove any physically exposed portion of the outer blocking dielectric layers (not shown) from around the through-via cavities. Each through-via cavity is a contact via cavity to which a surface of a respective electrically conductive layer 46 is physically exposed. In one embodiment, each through-via cavity comprises a respective annular recess region to which a cylindrical sidewall of a respective electrically conductive layer 46 is physically exposed.

At least one electrically conductive material, such as a combination of a metallic barrier liner material and a metal fill material, can be conformally deposited in the through-via cavities directly on physically exposed surface segments of the electrically conductive layers 46. Excess portions of the at least one electrically conductive material may be removed from above the horizontal plane including the top surface of the contact-level dielectric layer 80 by a planarization process, which may comprise a recess etch process and/or a chemical mechanical polishing process. Each remaining portion of the at least one electrically conductive material filling a respective one of the through-via cavities constitute a layer contact via structure 86. The layer contact via structures 86 comprise first-tier-contact layer contact via structures 861 that contact a respective one of the first-tier electrically conductive layers 146, and second-tier-contact layer contact via structures 862 that contact a respective one of the second-tier electrically conductive layers.

Each layer contact via structure 86 vertically extends through a respective retro-stepped dielectric material portion (165, or 265) and a set of at least one electrically conductive layer 46 located within a same tier structure as the respective retro-stepped dielectric material portion (165, or 265) and underlies the respective retro-stepped dielectric material portion (165, or 265). Each layer contact via structure 86 is electrically connected to and is in direct contact with a topmost electrically conductive layer 46 within the set of at least one electrically conductive layer 46. If the set of at least one electrically conductive layer 46 comprises a plurality of electrically conductive layers 46, the layer contact via structure 86 is laterally spaced from, and is electrically isolated from, each electrically conductive layer 46 within the set except the topmost electrically conductive layer 46 within the set by at least one annular insulating spacer 22. In case the layer contact via structure 86 vertically extends through any opening in any other electrically conductive layer 46 that overlies the tier structure or underlies the tier structure, the layer contact via structure 86 is laterally spaced from and is electrically isolated from any such electrically conductive layer 46 by a respective annular insulating spacer 22.

In an alternative embodiment, the annular insulating spacers 22, the thickening of the sacrificial material layers 42, and thickened electrically conductive layer 46 portions may be omitted. In this alternative embodiment, the layer contact via structures 86 extend only to the top horizontal surface of the topmost electrically conductive layer 46 exposed in stepped (i.e., staircase) portion of the inter-array region 200. Thus, the layer contact via structures 86 do not extend below the electrically conductive layer 46 which its contacted by the respective structure 86.

Drain contact via structures 88 can be formed through the contact-level dielectric layer 80 on the drain regions 63 within the memory opening fill structures 58. Each drain region 634 may be contacted by a respective one of the drain contact via structures 88.

In this embodiment, even numbered dielectric wall structures 76 may contact only the retro-stepped dielectric material portions (165, 265) but not the dielectric pillar structures (226), while odd numbered dielectric wall structures 76 may contact only the dielectric pillar structures (226) but not the retro-stepped dielectric material portions (165, 265), or vice-versa.

Each alternating stack (32, 46) located between adjacent dielectric wall structures 76 comprises a memory block. A continuous electrically conductive path (e.g., a conductive bridge region) 300 extends through each inter-array region 200 between the first memory array region 100A and the second memory array region 100B. Thus, each electrically conductive layer 46 continuously extends through each inter-array region 200 between the first memory array region 100A and the second memory array region 100B in the bridge region 300.

Suitable additional processing steps may be performed as needed. For example, bit lines and metal interconnect structures embedded within dielectric material layers can be formed over the contact-level dielectric layer. Bonding pads may be formed at the uppermost level of the dielectric material layers to provide at least one memory die. Each memory die may be bonded to a respective logic die including a controller circuit for operation of a three-dimensional array in a memory die. A wafer-to-wafer bonding, a wafer-to-die bonding, or a die-to-die bonding may be employed. The semiconductor material layer 110 may be thinned and/or removed as needed. In this case, source layers (not shown) may be formed on the bottom surfaces of the vertical semiconductor channels 60.

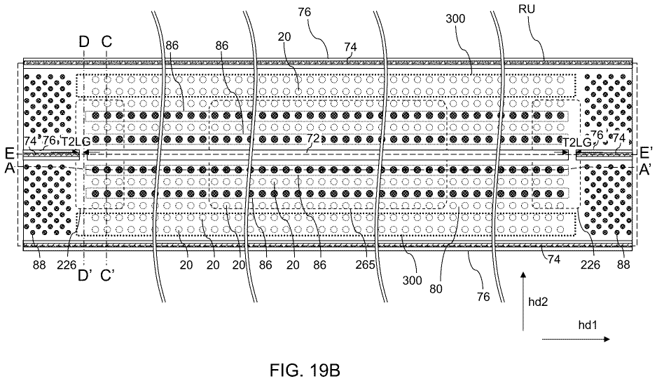

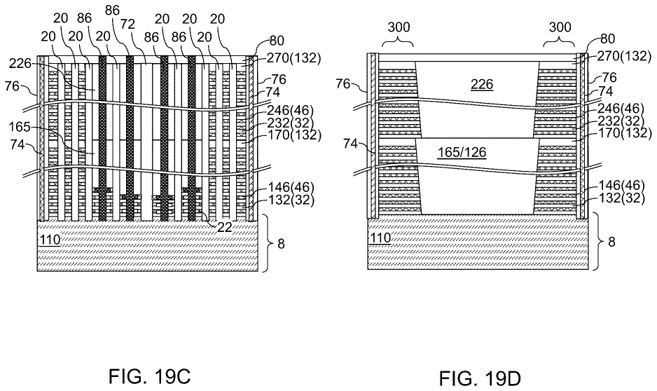

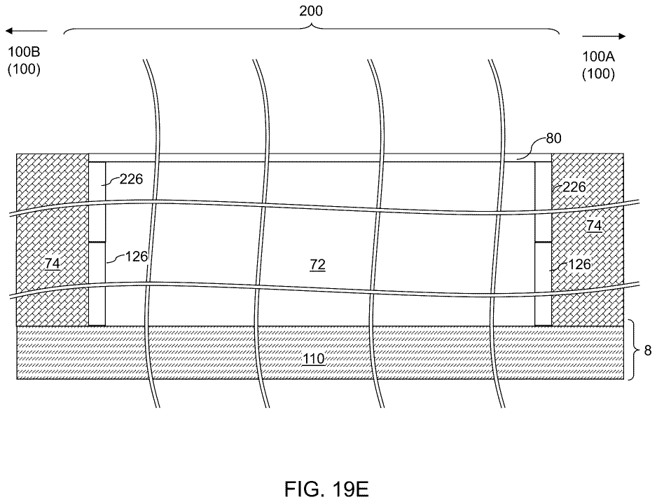

Referring to FIG. 19A-19E, in a first alternative embodiment, a first alternative configuration of the exemplary structure may be derived from exemplary structure of FIGS. 18A-18E by embedding an electrically conductive local interconnect 74 in each dielectric wall structure 76. The local interconnect 74 may contact the source region of the memory device which underlies the alternating stack (32, 46). The source region may comprise the semiconductor material layer 110 or another heavily doped semiconductor layer which is deposited on the bottom of the alternating stack (32, 46) and exposed bottom ends of the vertical semiconductor channels 60 after removing the substrate 8. In this embodiment, the dielectric wall structure 76 comprises a dielectric liner which surrounds the local interconnect 74 and which isolates the local interconnect 74 from the electrically conductive layers 46. The local interconnect 74 may comprise any suitable electrically conductive material, such as a TiN barrier layer and tungsten fill layer embedded in the barrier layer. In contrast, the complementary dielectric wall structure 72 consists of a dielectric material (e.g., silicon oxide) and does not embed any electrically conductive local interconnect 74.

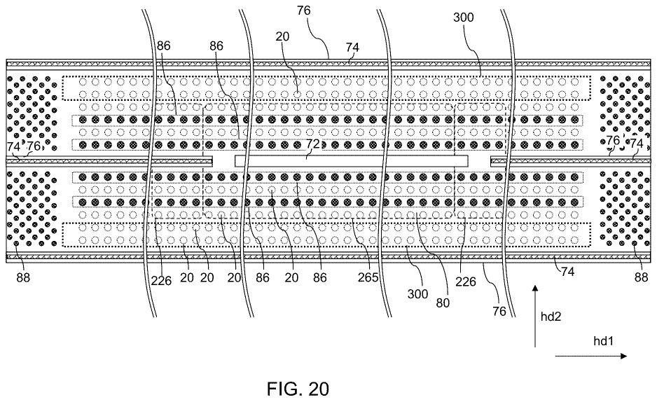

Referring to FIG. 20, in a second alternative embodiment, a second alternative configuration of the exemplary structure may be derived from exemplary structure of FIG. 18B or 19B by forming the dielectric pillar structures 226 in contact with the opposite ends of the retro-stepped dielectric material portions 265. In this alternative embodiment, the dielectric pillar structures 226 located in the second tier are similar to the first-tier dielectric separators 126.

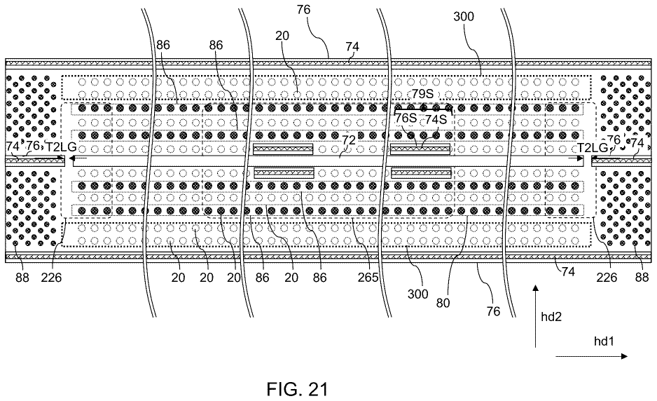

Referring to FIG. 21, in a third alternative embodiment, a third alternative configuration of the exemplary structure may be derived from exemplary structure of FIGS. 18A, 19B or 20 by forming supporting lateral isolation trenches 79S which are filled with a supporting dielectric wall structure 76S and optionally a supporting local interconnect 74S. The supporting lateral isolation trenches 79S may be used to replace the sacrificial material layers 42 with electrically conductive layers 46. In other words, the step of selectively etching the sacrificial material layers 42 shown in FIG. 16A-16E may be conducted through both the lateral isolation trenches 79 and the supporting lateral isolation trenches 79S at the same time. Likewise, the electrically conductive layers 46 may be deposited into the laterally-extending cavities 43 through both the lateral isolation trenches 79 and the supporting lateral isolation trenches 79S at the same time. The lateral isolation trenches 79 and the supporting lateral isolation trenches 79S are subsequently filled with the respective dielectric wall structures (76, 76S) and optionally the respective local interconnects (74, 74S) at the same time. The supporting lateral isolation trenches 79S are located near the complementary dielectric wall structure 72 along the second horizontal direction hd2 and help ensure that the laterally-extending cavities 43 located in the bridge regions 300 are filled with the electrically conductive layers 46 to establish the continuous electrically conductive path between the memory array regions (100A, 100B). In this embodiment, the a row of dielectric support pillar structures 20 may separate the complementary dielectric wall structure 72 from the nearest row of layer contact via structures 86 along the second horizontal direction.

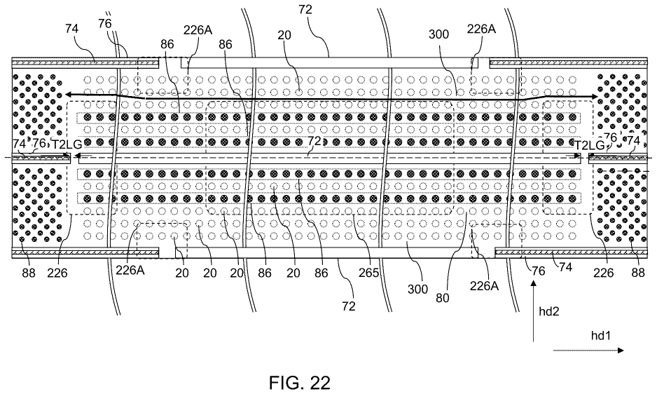

Referring to FIG. 22, in a fourth alternative embodiment, a fourth alternative configuration of the exemplary structure may be derived from exemplary structures of FIGS. 18A, 19B, 20 or 21 by forming the complementary dielectric wall structures 72, the dielectric pillar structures 226 and the lateral gaps which are located in all lateral isolation trenches 79 rather than in every other lateral isolation trench 79 along the second horizontal direction hd2. In this embodiment, the continuous electrically conductive path in the bridge region 300 may be curved instead of extending straight along the first horizontal direction hd1. Furthermore, the lateral gaps located in the even numbered lateral isolation trenches may be laterally offset from the lateral gaps located in the odd numbered lateral isolation trenches along the first horizontal direction hd1.

Referring to all drawings and according to various embodiments of the present disclosure, a semiconductor structure is provided, which comprises: a pair of multi-tier layer stacks {(132, 146), (232, 246)} laterally extending along a first horizontal direction hd1 and laterally spaced apart from each other along a second horizontal direction hd2 by a first lateral isolation structure (76, 72, 126, 226), wherein each of the multi-tier layer stacks {(132, 146), (232, 246)} comprises a first-tier alternating stack (132, 146) of first insulating layers 132 and first electrically conductive layers 146, and further comprises a second-tier alternating stack (232, 246) of second insulating layers 232 and second electrically conductive layers 246 that overlies the first-tier alternating stack (132, 146), wherein the semiconductor structure comprises a first memory array region 100A and a second memory array region 100B that are laterally spaced apart from each other along the first horizontal direction hd1 by an inter-array region 200; memory openings 49 vertically extending through a respective one of the multi-tier layer stacks {(132, 146), (232, 246)} and located in a respective one of the first memory array region 100A and the second memory array region 100B; and memory opening fill structures 58 located in a respective one of the memory openings 49 and comprising a vertical semiconductor channel 60 and respective vertical stack of memory elements (e.g., portions of the memory film 50). The first lateral isolation structure (76, 72, 126, 226) comprises: a first primary dielectric wall structure 76 laterally extending through the first memory array region 100A and extending into a first peripheral portion of the inter-array region 200; a complementary dielectric wall structure 72 laterally extending through the inter-array region 200 laterally spaced from the first primary dielectric wall structure 76 by a first lateral gap T2LG along the first horizontal direction hd1; and a first dielectric pillar structure 226 that fills the first lateral gap T2LG and contacts the first primary dielectric wall structure 76 and the complementary dielectric wall structure 72.

In one embodiment, the first lateral isolation structure (76, 72, 126, 226) further comprises: a second primary dielectric wall structure 86 laterally extending through the second memory array region 100B and extending into a second peripheral portion of the inter-array region 200, wherein the second primary dielectric wall structure 76 is laterally spaced from the complementary dielectric wall structure 72 by a second lateral gap T2LG; and a second dielectric pillar structure 226 that fills the second lateral gap and contacts the second primary dielectric wall structure 76 and the complementary dielectric wall structure 72.

In one embodiment, the first dielectric pillar structure 226 is located entirely above a horizontal plane including topmost surfaces of the first-tier alternating stacks (132, 146). In one embodiment, the first primary dielectric wall structure 76 and the complementary dielectric wall structure 72 has a first width along the second horizontal direction hd2; and the first dielectric pillar structure 226 has a second width along the second horizontal direction hd2 that is greater than the first width.

In one embodiment, the semiconductor structure further comprises a first-tier retro-stepped dielectric material portion 165 embedded within a respective first-tier alternating stack (132, 146) within the pair of multi-tier layer stacks {(132, 146), (232, 246)}, wherein the first dielectric pillar structure 226 contacts a top surface of the first-tier retro-stepped dielectric material portion 165. In one embodiment the first-tier retro-stepped dielectric material portion 165 comprises a first-tier dielectric separator 126 portion which is located under the first dielectric pillar structure 226, and which vertically extends through an entire height of the first alternating stack, and constitutes a portion of the first lateral isolation structure (76, 72, 126, 226).

In one embodiment, the semiconductor structure also comprises layer contact via structures 86 located in the inter-array region 200 and contacting a respective one of the first electrically conductive layers 146 and the second electrically conductive layers 246. In one embodiment, the semiconductor structure also comprises support pillar structures 20 vertically extending through a respective one of the first-tier retro-stepped dielectric material portions 165, a respective one of the second-tier structures, and a respective one of the first-tier structures and comprising a same set of at least one dielectric material as the complementary dielectric wall structure 72.

In one embodiment, the semiconductor structure also comprises a second-tier retro-stepped dielectric material portion 265 embedded within the second-tier alternating stack (232, 246). In some embodiments, the second-tier retro-stepped dielectric material portion 265 is laterally spaced from the first dielectric pillar structure 226 along the first horizontal direction hd1. In the second alternative embodiment illustrated in FIG. 20, the second-tier retro-stepped dielectric material portion 265 contacts the first dielectric pillar structure 226.

In one embodiment, a first end wall of the complementary dielectric wall structure 72 is more proximal to the first memory array region 100A than the second-tier retro-stepped dielectric material portion 265 is to the first memory array region 100A; the first dielectric pillar structure 226 is located between the first end wall of the complementary dielectric wall structure 72 and the first memory array region 100A; a second end wall of the complementary dielectric wall structure 72 is more proximal to the second memory array region 100B than the second-tier retro-stepped dielectric material portion 265 is to the second memory array region 100B; and a second dielectric pillar structure 226 is located between the second end wall of the complementary dielectric wall structure 72 and the second memory array region 100B.

In the first alternative embodiment illustrated in FIG. 19A-19E, a first electrically conductive local interconnect 74 is embedded in the first primary dielectric wall structure 76; and a second electrically conductive local interconnect 74 is embedded in the second primary dielectric wall structure 76, wherein the complementary dielectric wall structure 72 consists essentially of an electrically insulating material (e.g., silicon oxide) and does not embed an electrically conductive local interconnect. In this embodiment, a third multi-tier stack is laterally separated from one of the pair of multi-tier layer stacks along the second horizontal direction hd2 by a third primary dielectric wall structure 76 which extends continuously through the first memory array region 100A, the inter-array region 200 and the second memory array region 100B. A third electrically conductive local interconnect 74 is embedded in the third primary dielectric wall structure 76 and extends continuously through the first memory array region 100A, the inter-array region 200 and the second memory array region 100B.

In the third alternative embodiment illustrated in FIG. 21, supporting lateral isolation trenches 79S extend through the pair of multi-tier layer stacks in the inter-array region 200; and supporting dielectric wall structures 76S are located in the supporting lateral isolation trenches 79S and embed supporting electrically conductive local interconnects 74S.

In one embodiment, the first electrically conductive layers 146 and the second electrically conductive layers 246 continuously extend from the first memory array region 100A to the second memory array region 100B through a bridge region 300 in the inter-array region 200.

The lateral isolation structures (72, 76, 126, 226) may enhance mechanical stability during replacement of the sacrificial material layers 42 with electrically conductive layers 46 by reducing or eliminating tilting of the alternating stacks (32, 46) into the lateral isolation trenches 79. Furthermore, by separately forming the dielectric pillar structures 226 at the same time as the retro-stepped dielectric material portion 265 prior to forming the complementary dielectric wall structure 72 simplifies the overall process of forming the lateral isolation structures (72, 76, 126, 226).

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a pair of multi-tier layer stacks laterally extending along a first horizontal direction and laterally spaced apart from each other along a second horizontal direction by a first lateral isolation structure, wherein each of the multi-tier layer stacks comprises a first-tier alternating stack of first insulating layers and first electrically conductive layers, and further comprises a second-tier alternating stack of second insulating layers and second electrically conductive layers that overlies the first-tier alternating stack, wherein the semiconductor structure comprises a first memory array region and a second memory array region that are laterally spaced apart from each other along the first horizontal direction by an inter-array region;
memory openings vertically extending through a respective one of the multi-tier layer stacks and located in a respective one of the first memory array region and the second memory array region; and
memory opening fill structures located in a respective one of the memory openings and comprising a vertical semiconductor channel and a respective vertical stack of memory elements,
wherein the first lateral isolation structure comprises:
a first primary dielectric wall structure laterally extending through the first memory array region and extending into a first peripheral portion of the inter-array region;
a complementary dielectric wall structure laterally extending through the inter-array region and laterally spaced from the first primary dielectric wall structure by a first lateral gap along the first horizontal direction; and
a first dielectric pillar structure that fills the first lateral gap and contacts the first primary dielectric wall structure and the complementary dielectric wall structure.

2. The semiconductor structure of claim 1, wherein the first lateral isolation structure further comprises:
a second primary dielectric wall structure laterally extending through the second memory array region and extending into a second peripheral portion of the inter-array region, wherein the second primary dielectric wall structure is laterally spaced from the complementary dielectric wall structure by a second lateral gap; and
a second dielectric pillar structure that fills the second lateral gap and contacts the second primary dielectric wall structure and the complementary dielectric wall structure.

3. The semiconductor structure of claim 2, wherein the first dielectric pillar structure is located entirely above a horizontal plane including topmost surfaces of the first-tier alternating stacks.

4. The semiconductor structure of claim 2, wherein:
the first primary dielectric wall structure and the complementary dielectric wall structure has a first width along the second horizontal direction; and
the first dielectric pillar structure has a second width along the second horizontal direction that is greater than the first width.

5. The semiconductor structure of claim 2, further comprising a first-tier retro-stepped dielectric material portion embedded within a respective first-tier alternating stack within the pair of multi-tier layer stacks, wherein the first dielectric pillar structure contacts a top surface of the first-tier retro-stepped dielectric material portion.

6. The semiconductor structure of claim 5, wherein the first-tier retro-stepped dielectric material portion comprises a first-tier dielectric separator portion which is located under the first dielectric pillar structure, and which vertically extends through an entire height of the first alternating stack, and constitutes a portion of the first lateral isolation structure.

7. The semiconductor structure of claim 5, further comprising layer contact via structures located in the inter-array region and contacting a respective one of the first electrically conductive layers and the second electrically conductive layers.

8. The semiconductor structure of claim 5, further comprising support pillar structures vertically extending through a respective one of the first-tier retro-stepped dielectric material portions, a respective one of the second-tier structures, and a respective one of the first-tier structures and comprising a same set of at least one dielectric material as the complementary dielectric wall structure.

9. The semiconductor structure of claim 5, further comprising a second-tier retro-stepped dielectric material portion embedded within the second-tier alternating stack.

10. The semiconductor structure of claim 9, wherein the second-tier retro-stepped dielectric material portion is laterally spaced from the first dielectric pillar structure along the first horizontal direction.

11. The semiconductor structure of claim 9, wherein the second-tier retro-stepped dielectric material portion contacts the first dielectric pillar structure along the first horizontal direction.

12. The semiconductor structure of claim 9, wherein:
a first end wall of the complementary dielectric wall structure is more proximal to the first memory array region than the second-tier retro-stepped dielectric material portion is to the first memory array region;
the first dielectric pillar structure is located between the first end wall of the complementary dielectric wall structure and the first memory array region;
a second end wall of the complementary dielectric wall structure is more proximal to the second memory array region than the second-tier retro-stepped dielectric material portion is to the second memory array region;
a second dielectric pillar structure is located between the second end wall of the complementary dielectric wall structure and the second memory array region.

13. The semiconductor structure of claim 2, further comprising:
a first electrically conductive local interconnect embedded in the first primary dielectric wall structure; and
a second electrically conductive local interconnect embedded in the second primary dielectric wall structure, wherein the complementary dielectric wall structure consists essentially of an electrically insulating material and does not embed an electrically conductive local interconnect.

14. The semiconductor structure of claim 13, further comprising:
a third multi-tier stack which is laterally separated from one of the pair of multi-tier layer stacks along the second horizontal direction by a third primary dielectric wall structure which extends continuously through the first memory array region, the inter-array region and the second memory array region; and
a third electrically conductive local interconnect embedded in the third primary dielectric wall structure and extending continuously through the first memory array region, the inter-array region and the second memory array region.

15. The semiconductor structure of claim 13, further comprising:
supporting lateral isolation trenches extending through the pair of multi-tier layer stacks in the inter-array region; and
supporting dielectric wall structures located in the supporting lateral isolation trenches and embedding supporting electrically conductive local interconnects.

16. The semiconductor structure of claim 1, wherein the first electrically conductive layers and the second electrically conductive layers continuously extend from the first memory array region to the second memory array region through a bridge region in the inter-array region.

17. A method of forming a semiconductor structure, comprising:
forming a first-tier structure comprising first-tier alternating stacks of first insulating layers and first sacrificial material layers, wherein the first-tier alternating stacks laterally extend along a first horizontal direction and are laterally spaced apart from each other by sacrificial first-tier wall structures;
forming a second-tier structure comprising second-tier alternating stacks of second insulating layers and second sacrificial material layers over the first-tier structure, wherein the second-tier alternating stacks laterally extend along the first horizontal direction and are laterally spaced apart from each other by second-tier lateral spacer structures, wherein a neighboring pair of second-tier alternating stacks is laterally spaced apart from each other by a first second-tier lateral spacer structure of the second-tier lateral spacer structures, and wherein the first second-tier lateral spacer structure comprises a combination of at least one primary sacrificial second-tier wall structure, a complementary sacrificial second-tier wall structure that is laterally spaced from the at least one primary sacrificial second-tier wall structure by at least one second-tier lateral gap, and at least one dielectric pillar structure filling the at least one second-tier lateral gap;
forming memory openings in a first memory array region and in a second memory array region at least through a respective vertical stack of a respective one of the first-tier alternating stacks and through a respective one of the second-tier alternating stacks;
forming memory opening fill structures in the memory openings, wherein each of the memory opening fill structures comprises a vertical semiconductor channel and a respective vertical stack of memory elements;
replacing the complementary sacrificial second-tier wall structure and a first portion of one of the sacrificial first-tier wall structures with a complementary dielectric wall structure;
forming lateral isolation trenches by removing the at least one primary sacrificial second-tier wall structure and remaining portions of said one of the sacrificial first-tier wall structures; and
replacing remaining portions of the first sacrificial material layers and remaining portions of the second sacrificial material layers with first electrically conductive layers and second electrically conductive layers, respectively.

18. The method of claim 17, further comprising:
forming support openings through the first-tier structure and through the second-tier structure; and
depositing at least one dielectric material in the support openings and in a line trench that is formed by removal of the complementary sacrificial second-tier wall structure and the first portion of one of the sacrificial first-tier wall structures to form support pillar structures in the support openings and to form the complementary dielectric wall structure in the line trench.

19. The method of claim 17, further comprising filling the lateral isolation trenches with at least one dielectric fill material embedding a respective electrically conductive local interconnect to form a first primary dielectric wall structure and a second primary dielectric wall structure within two of the lateral isolation trenches.

20. The method of claim 19, wherein:
bottom surfaces of the first-tier alternating stacks are formed within a first horizontal plane;
bottom surfaces of the second-tier alternating stacks are formed within a second horizontal plane;
top surfaces of the second-tier alternating stacks are formed within a third horizontal plane;
an entire bottom surface of each of the at least one dielectric pillar structure is formed within the second horizontal plane; and
an entire top surface of each of the at least one dielectric pillar structure is formed within the third horizontal plane.
